(19) United States
(12) Patent Application Publication
(10) Pub. No.: US 2012/0043517 A1
(43) Pub. Date: Feb. 23, 2012

(54) NONVOLATILE SEMICONDUCTOR STORAGE DEVICE

(75) Inventor: Takeshi Sonehara, Yokkaichi-shi (JP)

(73) Assignee: Kabushiki Kaisha Toshiba, Tokyo (JP)

(21) Appl. No.: 13/208,955

(22) Filed: Aug. 12, 2011

(30) Foreign Application Priority Data
Aug. 17, 2010 (JP) 2010-182403

(51) Int. Cl. H01L 47/00

(52) U.S. Cl. 257/2; 257/E47.001

(57) ABSTRACT

A nonvolatile semiconductor storage device according to an embodiment includes a first line; a second line that intersects the first line; and a memory cell that includes a memory element and a non-ohmic element, the memory cell being provided at the intersection of the first line and the second line while the memory element and the non-ohmic element are series-connected, data being stored in the memory element according to a change of a resistance state, wherein the non-ohmic element includes a metallic layer, an intrinsic semiconductor layer that is joined to the metallic layer, and a doped semiconductor layer that is joined to the intrinsic semiconductor layer and contains a first dopant.

### CROSS-REFERENCE TO RELATED APPLICATIONS

This application is based upon and claims the benefit of priority from the prior Japanese Patent Application No. 2010-182403, filed on Aug. 17, 2010, the entire contents of which are incorporated herein by reference.

### FIELD

Embodiments described herein relate to a nonvolatile semiconductor storage device.

### BACKGROUND

Recently electrically-rewritable variable resistive elements, such as a ReRAM, a PRAM, and a PCRAM, which are a nonvolatile semiconductor storage device attract attention as a memory of a successor memory to a flash memory.

The variable resistive element of the ReRAM includes variable resistive material/electrode such as electrode/(binary or ternary) metal oxide. There are two ways of operating the variable resistive element, namely, a bipolar operation in which a high resistance state and a low resistance state are switched by changing a polarity of an applied voltage, and a unipolar operation in which the high resistance state and the low resistance state are switched by controlling the applied voltage and a voltage application time without changing the polarity of the applied voltage.

Regarding the bipolar operation, conventional rectifying elements such as PIN diodes cannot provide a sufficient reverse-direction current necessary in a reverse bias on region. In addition it cannot suppress an off current sufficiently in an off region. Therefore, when such a conventional rectifying element is used for a memory cell of bipolar operation, it is difficult to secure a good operation characteristics of the memory cell.

### BRIEF DESCRIPTION OF THE DRAWINGS

FIG. 1 is a block diagram of a nonvolatile semiconductor storage device according to a first embodiment;

FIG. 2 is a view illustrating disposition combinations of a rectifying element and a memory element of a memory cell in the nonvolatile semiconductor storage device of the first embodiment;

FIG. 3 is a view illustrating a state in which a current passed through a selected memory cell and a current passed through a non-selected memory cell in the nonvolatile semiconductor storage device of the first embodiment;

FIG. 4 is a view illustrating a bias state when the nonvolatile semiconductor storage device of the first embodiment is operated in a unipolar operation;

FIG. 5 is a view illustrating a bias state when the nonvolatile semiconductor storage device of the first embodiment is operated in a bipolar operation;

FIG. 6 is a view illustrating an example of a current-voltage characteristic of a desirable rectifying element when the nonvolatile semiconductor storage device of the first embodiment is operated in the bipolar operation;

FIG. 7 is a view illustrating a structure of the memory cell in the nonvolatile semiconductor storage device of the first embodiment;

FIG. 8 is a view illustrating a state of an energy band in an equilibrium state of a PIM diode in the nonvolatile semiconductor storage device of the first embodiment;

FIG. 9 is a view illustrating a state of the energy band when a forward bias is applied to the PIM diode in the nonvolatile semiconductor storage device of the first embodiment;

FIG. 10 is a view illustrating a state of the energy band when a reverse bias is applied to the PIM diode in the nonvolatile semiconductor storage device of the first embodiment;

FIG. 11 is a view illustrating a current-voltage characteristic of the PIM diode in the nonvolatile semiconductor storage device of the first embodiment;

FIG. 12 is a view illustrating a structure of a memory cell in a nonvolatile semiconductor storage device according to a second embodiment;

FIG. 13 is a view illustrating a state of an energy band in an equilibrium state of a PIM diode in the nonvolatile semiconductor storage device of the second embodiment;

FIG. 14 is a view illustrating a state of the energy band when the forward bias is applied to the PIM diode in the nonvolatile semiconductor storage device of the second embodiment;

FIG. 15 is a view illustrating a current-voltage characteristic of the PIM diode in the nonvolatile semiconductor storage device of the second embodiment when a Schottky barrier height (SBH) is changed;

FIG. 16 is a view illustrating a state of the energy band when the reverse bias is applied to the PIM diode in the nonvolatile semiconductor storage device of the second embodiment;

FIG. 17 is a view illustrating another structure of the memory cell in the nonvolatile semiconductor storage device of the second embodiment;

FIG. 18 is a view illustrating another structure of the memory cell in the nonvolatile semiconductor storage device of the second embodiment;

FIG. 19 is a view illustrating another structure of the memory cell in the nonvolatile semiconductor storage device of the second embodiment;

FIG. 20 is a view illustrating another structure of the memory cell in the nonvolatile semiconductor storage device of the second embodiment;

FIG. 21 is a view illustrating another structure of the memory cell in the nonvolatile semiconductor storage device of the second embodiment;

FIG. 22 is a view illustrating a structure of a memory cell in a nonvolatile semiconductor storage device according to a third embodiment;

FIG. 23 is a view illustrating a structure of the memory cell in the nonvolatile semiconductor storage device of the third embodiment;

FIG. 24 is a view illustrating another structure of the memory cell in the nonvolatile semiconductor storage device of the third embodiment;

FIG. 25 is a view illustrating another structure of the memory cell in the nonvolatile semiconductor storage device of the third embodiment;

FIG. 26 is a view illustrating another structure of the memory cell in the nonvolatile semiconductor storage device of the third embodiment;

FIG. 27 is a view illustrating another structure of the memory cell in the nonvolatile semiconductor storage device of the third embodiment;

FIG. 28 is a view illustrating a change of a current-voltage characteristic generated by applying a stress voltage in the PIM diode of the nonvolatile semiconductor storage devices of the first to third embodiments;

FIG. 29 is a view illustrating a cause of the change of the current-voltage characteristic in the PIM diode of FIG. 28;

FIG. 30 is a view illustrating the cause of the change of the current-voltage characteristic in the PIM diode of FIG. 28;

FIG. 31 is a view illustrating a structure of a memory cell in a nonvolatile semiconductor storage device according to a fourth embodiment;

FIG. 32 is reference data illustrating a function of the PIM diode in the nonvolatile semiconductor storage device of the fourth embodiment;

FIG. 33 is another piece of reference data illustrating the function of the PIM diode in the nonvolatile semiconductor storage device of the fourth embodiment;

FIG. 34 is another piece of reference data illustrating the function of the PIM diode in the nonvolatile semiconductor storage device of the fourth embodiment;

FIG. 35 is a view illustrating another structure of the memory cell in the nonvolatile semiconductor storage device of the fourth embodiment;

FIG. 36 is a view illustrating another structure of the memory cell in the nonvolatile semiconductor storage device of the fourth embodiment;

FIG. 37 is a view illustrating another structure of the memory cell in the nonvolatile semiconductor storage device of the fourth embodiment;

FIG. 38 is a view illustrating another structure of the memory cell in the nonvolatile semiconductor storage device of the fourth embodiment;

FIG. 39 is a view illustrating another structure of the memory cell in the nonvolatile semiconductor storage device of the fourth embodiment;

FIG. 40 is a view illustrating another structure of the memory cell in the nonvolatile semiconductor storage device of the fourth embodiment;

FIG. 41 is a view illustrating another structure of the memory cell in the nonvolatile semiconductor storage device of the fourth embodiment;

FIG. 42 is a view illustrating another structure of the memory cell in the nonvolatile semiconductor storage device of the fourth embodiment;

FIG. 43 is a view illustrating another structure of the memory cell in the nonvolatile semiconductor storage device of the fourth embodiment;

FIG. 44 is a view illustrating another structure of the memory cell in the nonvolatile semiconductor storage device of the fourth embodiment;

FIG. 45 is a view illustrating another structure of the memory cell in the nonvolatile semiconductor storage device of the fourth embodiment;

FIG. 46 is a view illustrating another structure of the memory cell in the nonvolatile semiconductor storage device of the fourth embodiment;

FIG. 47 is a view illustrating another structure of the memory cell in the nonvolatile semiconductor storage device of the fourth embodiment;

FIG. 48 is a view illustrating another structure of the memory cell in the nonvolatile semiconductor storage device of the fourth embodiment;

FIG. 49 is a view illustrating another structure of the memory cell in the nonvolatile semiconductor storage device of the fourth embodiment;

FIG. 50 is a view illustrating another structure of the memory cell in the nonvolatile semiconductor storage device of the fourth embodiment;

FIG. 51 is a view illustrating another structure of the memory cell in the nonvolatile semiconductor storage device of the fourth embodiment;

FIG. 52 is a view illustrating another structure of the memory cell in the nonvolatile semiconductor storage device of the fourth embodiment;

FIG. 53 is a view illustrating another structure of the memory cell in the nonvolatile semiconductor storage device of the fourth embodiment;

FIG. 54 is a view illustrating another structure of the memory cell in the nonvolatile semiconductor storage device of the fourth embodiment;

FIG. 55 is a view illustrating another structure of the memory cell in the nonvolatile semiconductor storage device of the fourth embodiment;

FIG. 56 is a view illustrating another structure of the memory cell in the nonvolatile semiconductor storage device of the fourth embodiment;

FIG. 57 is a view illustrating another structure of the memory cell in the nonvolatile semiconductor storage device of the fourth embodiment;

FIG. 58 is a view illustrating a structure of a memory cell in a nonvolatile semiconductor storage device according to a comparative example;

FIG. 59 is a view illustrating a state of an energy band when the forward bias is applied to a PIN diode of FIG. 58;

FIG. 60 is a view illustrating a state of the energy band when the reverse bias is applied to the PIN diode of FIG. 58; and

FIG. 61 is a view illustrating a current-voltage characteristic of the PIN diode of FIG. 58.

### DETAILED DESCRIPTION

According to an aspect of the invention, a nonvolatile semiconductor storage device includes a first line; a second line that intersects the first line; and a memory cell that includes a memory element and a non-ohmic element, the memory cell being provided at the intersection of the first line and the second line while the memory element and the non-ohmic element are series-connected, data being stored in the memory element according to a change of a resistance state, the non-ohmic element including a metallic layer, an intrinsic semiconductor layer that is joined to the metallic layer, and a doped semiconductor layer that is joined to the intrinsic semiconductor layer and contains a first dopant.

Hereinafter, semiconductor storage devices according to embodiments of the invention will be described with reference to the drawings.

### First Embodiment

<Entire System>

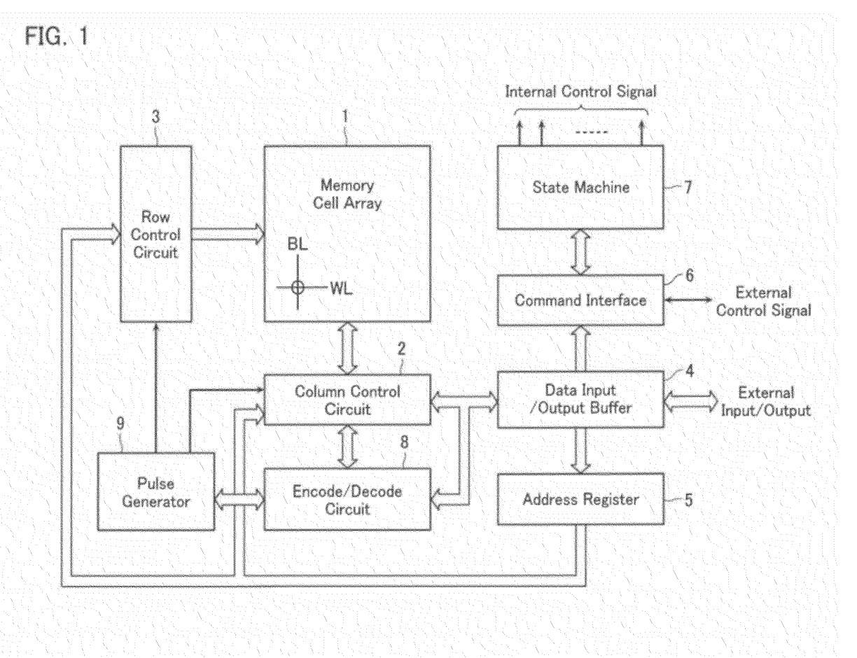

FIG. 1 is a block diagram of a nonvolatile semiconductor storage device according to a first embodiment.

The nonvolatile semiconductor storage device of the first embodiment includes a memory cell array 1. The memory cell array 1 includes plural word lines WL (first lines), plural bit lines BL (second lines) that intersect the word lines WL, and plural memory cells MC that are provided in intersections of the word lines WL and the bit lines BL. A column control circuit 2 is provided in a position adjacent to the memory cell array 1 in a direction of the bit line BL. The column control circuit 2 controls the bit line BL of the memory cell array 1 to erase data of the memory cell MC, to write the data in the memory cell MC, and to read the data from the memory cell MC. A row control circuit 3 is provided in a position adjacent to the memory cell array 1 in a direction of the word line WL. The row control circuit 3 selects the word line WL of the memory cell array 1 to apply a voltage necessary to erase the data of the memory cell MC, to write the data in the memory cell MC, and to read the data from the memory cell MC.

A data input/output buffer 4 is connected to an external host (not illustrated) through an input/output line to receive the write data, an erase command, address data, and command data and to output the read data. The data input/output buffer 4 transmits the received write data to the column control circuit 2 and receives the data read from the column control circuit 2 to output the data to the outside. An address supplied from the outside to the data input/output buffer 4 is transmitted to the column control circuit 2 and the row control circuit 3 through an address register 5. A command supplied from a host to the data input/output buffer 4 is transmitted to a command interface 6. The command interface 6 receives an external control signal from the host to determine whether the data input to the data input/output buffer 4 is the write data, the command, or the address. When the data is the command, the command interface 6 receives the command to transfer the command as a command signal to a state machine 7. The state machine 7 manages the whole nonvolatile semiconductor storage device. The state machine 7 performs the reception, the read, the write, and the erase of the command from the host and input/output management of the data.

The data input from the host to the data input/output buffer 4 is transferred to an encode/decode circuit 8, and an output signal of the encode/decode circuit 8 is input to a pulse generator 9 that is a write voltage generating circuit. In response to the input signal, the pulse generator 9 outputs a write pulse having a predetermined voltage at predetermined timing. The pulse generated by and output from the pulse generator 9 is transferred to a specific interconnection selected by the column control circuit 2 and the row control circuit 3.

<Memory Cell>

The memory cell MC used in the nonvolatile semiconductor storage device of the first embodiment will be described below.

The memory cell MC of the first embodiment includes a memory element and a non-ohmic element, which are series-connected in an intersection of the word line WL and the bit line BL.

A variable resistive element or a phase-change element is used as the memory element of the first embodiment. The variable resistive element is made of a material whose resistance value is changed by the voltage, current, heat and the like. The phase-change element is made of a material whose physical property such as the resistance value and a capacitance is changed by a phase change.

At this point, the phase change (phase transition) includes the following modes.

(1) Metal-semiconductor transition, metal-insulator transition, metal-metal transition, insulator-insulator transition, insulator-semiconductor transition, insulator-metal transition, semiconductor-semiconductor transition, semiconductor-metal transition, or semiconductor-insulator transition

(2) Quantum-state phase change such as metal-superconductor transition

(3) Paramagnetic material-ferromagnetic material transition, antiferromagnetic material-ferromagnetic material transition, ferromagnetic material-ferromagnetic material transition, ferrimagnetic material-ferromagnetic material transition, and a transition of a combination thereof

(4) Paraelectric material-ferroelectric material transition, paraelectric material-pyroelectric material transition, paraelectric material-piezoelectric material transition, ferroelectric material-ferroelectric material transition, antiferroelectric material-ferroelectric material transition, or a transition of a combination thereof

(5) A transition of a combination of the transitions (1) to (4), for example, a transition to a ferroelectric ferromagnetic material from the metal, insulator, semiconductor, ferroelectric material, paraelectric material, pyroelectric material, piezoelectric material, ferromagnetic material, ferrimagnetic material, helimagnetic material, paramagnetic material, or antiferromagnetic material, or a reverse transition thereof.

According to the definition, the phase-change element is included in the variable resistive element. However, in the first embodiment, the variable resistive element mainly means elements made of a metal oxide, a metal compound, an organic thin film, carbon and carbon nanotube.

The first embodiment is directed to an ReRAM in which the variable resistive element is used as the memory element and a resistance-change memory such as a PCRAM in which the phase-change element is used as the memory element. In the resistance-change memories, the memory cell array 1 is a cross-point type, a large memory capacity can be implemented by a three-dimensional integration, and DRAM-like high-speed operation can be achieved.

Hereinafter, the memory element will be mainly described as the variable resistive element such as the ReRAM, and the non-ohmic element will be mainly described as a diode that is a rectifying element.

For the memory cell array 1 having a three-dimensional structure, a positional relationship between the variable resistive element and the diode of the memory cell MC and a combination of diode orientations can variously be selected in each layer.

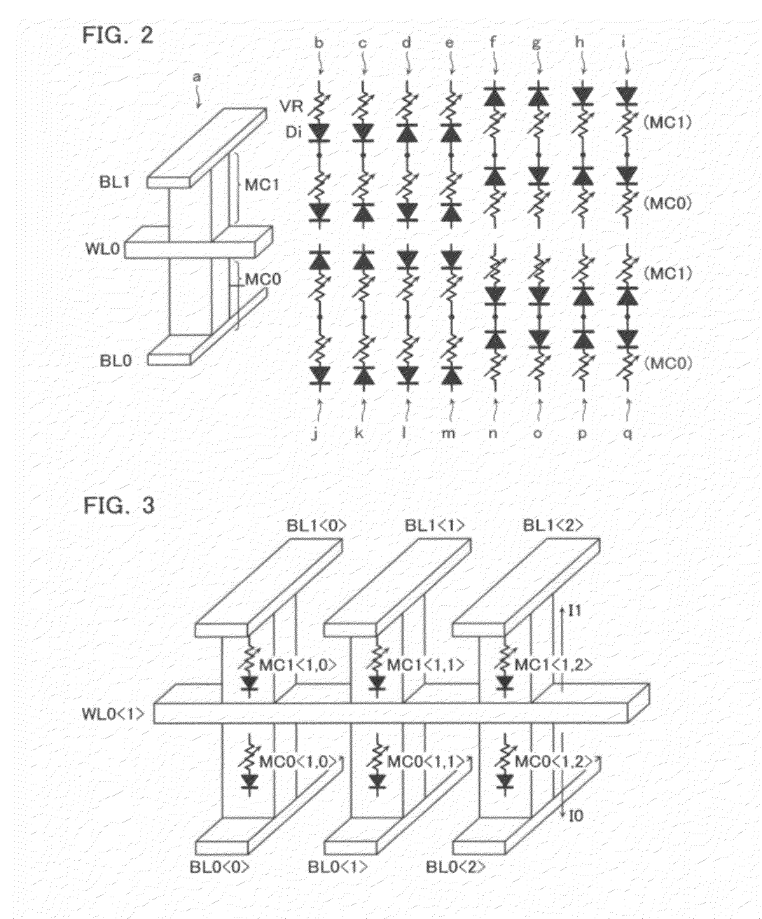

The part a in FIG. 2 illustrates combination patterns of a memory cell MC0 belonging to the lower memory cell array 1 and a memory cell MC1 belonging to the upper memory cell array 1 when a word line WL0 is shared by the memory cells MC0 and MC1. As illustrated in parts b to q of FIG. 2, 16 patterns are conceivable for the combinations of the memory cell MC0 and the memory cell MC1 by reversing a disposition relationship between a variable resistive element VR and a diode Di or orientations of the diodes Di. The patterns can be selected in consideration of the operating characteristic, an operating system, and a production process.

Then the operation to write and erase the data in and from the memory cell MC will be described. Hereinafter, the write operation to cause the variable resistive element VR to transition from a high resistance state to a low resistance state is referred to as a “set operation”, and the erase operation to cause the variable resistive element VR to transition from the low resistance state to the high resistance state is referred to as a “reset operation”. In the following description, a current value and a voltage value are cited by way of example. However, the current value and the voltage value depend on materials and dimensions of the variable resistive element VR and the diode Di.

FIG. 3 is a schematic diagram illustrating part of the memory cell array 1. Referring to FIG. 3, the lower memory cell MC0 is provided at an intersection of the bit line BL0 and the word line WL0. The upper memory cell MC1 is provided at the intersection of the word line WL0 and the bit line BL1. The word line WL0 is shared by the memory cells MC0 and MC1.

The disposition combination of the memory cells MC0 and MC1 in FIG. 3 is the same as the pattern b show in FIG. 2. That is, in the memory cell MC0, the diode Di and the variable resistive element VR are sequentially stacked from the bit line BL0 to the word line WL0. The diode Di is disposed such that a direction from the word line WL0 to the bit line BL0 is set to a forward direction of the diode Di. On the other hand, in the memory cell MC1, the diode Di and the variable resistive element VR are sequentially stacked from the word line WL0 to the bit line BL1. The diode Di is disposed such that a direction from the bit line BL1 to the word line WL0 is set to a forward direction of the diode Di.

The set operation and the reset operation will be described in the case where a memory cell MC0<1,1> provided at the intersection of a bit line BL0<1> and a word line WL0<1> is selected as the selected memory cell.

There are two ways of performing the set operation and the reset operation to the memory cell MC, namely, the unipolar operation in which the set operation and the reset operation are implemented by applying biases having the same polarity and the bipolar operation in which the set operation and the reset operation are implemented by applying biases having different polarities.

The unipolar operation will be described first.

In the set operation, it is necessary to apply a current having current density of 1×10⁵ to 1×10⁷ A/cm² or a voltage of 1 to 2 V to the variable resistive element VR. Accordingly, when the set operation is performed to the memory cell MC, it is necessary that the forward current be passed through the diode Di such that the predetermined current or voltage is applied to the variable resistive element VR.

In the reset operation, it is necessary to apply a current having current density of 1×10³ to 1×10⁶ A/cm² or a voltage of 1 to 3 V to the variable resistive element VR. Accordingly, when the reset operation is performed to the memory cell MC, it is necessary that the forward current be passed through the diode Di such that the predetermined current or voltage is applied to the variable resistive element VR.

In FIG. 3, the reset operation of the memory cell MC0<1,1> can be implemented by applying voltages of 3 V and 0 V to the word line WL0<1> and the bit line BL0<1>, which are connected to the memory cell MC0<1,1>, respectively.

As illustrated in FIG. 3, usually plural memory cells MC are connected to one word line WL or one bit line BL. At this point, not only is it necessary to apply the predetermined current or voltage to the selected memory cell MC, but also it is necessary to avoid the set operation and the reset operation from being performed in the non-selected memory cell MC.

In FIG. 3, when the voltage of 0 V is applied to the bit lines BL0<0> and BL0<2> similarly to the bit line BL0<1>, a forward current I0 is also passed through the non-selected memory cells MC0<1,0> and MC0<1,2> thus causing unexpected reset operation to be performed in the non-selected memory cells MC0<1,0> and MC0<1,2>. When the voltage of 0 V is applied to the bit lines BL1<0> to BL1<2>, the reverse bias is applied to the non-selected memory cells MC1<1,0> to MC1<1,2>. Therefore, it is necessary to suppress an off-current I1 such that the off-current I1 is not passed through the non-selected memory cells MC1<1,0> to MC1<1,2>.

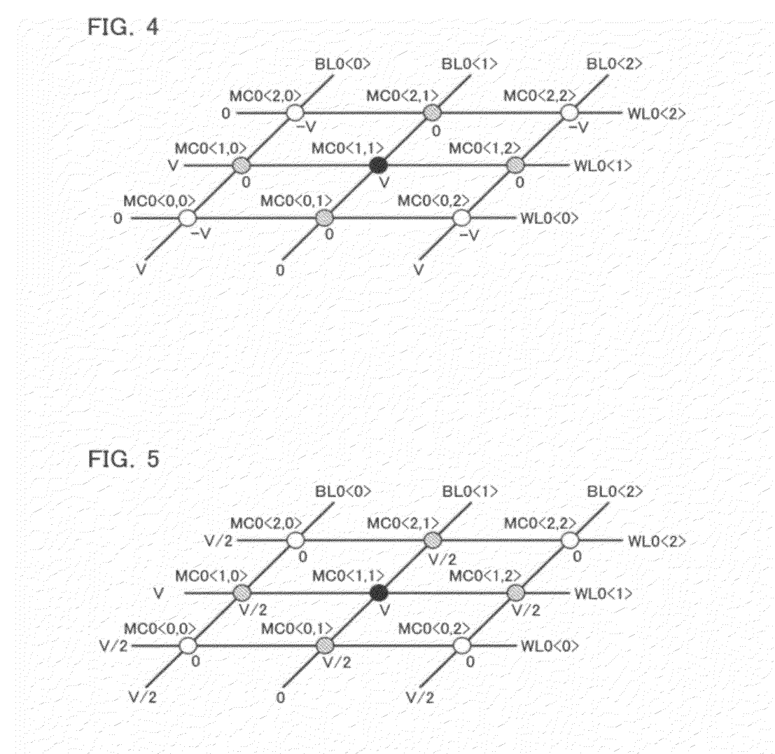

Therefore, when the unipolar operation is performed, for example, it is possible to apply the bias to the memory cell array 1 as illustrated in FIG. 4.

That is, the predetermined voltage V (for example, 3 V) is applied to the selected word line WL0<1>, and the voltage of 0 V is applied to other word lines WL0<0> and WL0<2>. The predetermined voltage of 0 V is applied to the selected bit line BL0<1>, and the voltage V is applied to other bit lines BL0<0> and BL0<2>.

As a result, the voltage V is applied to the selected memory cell MC0<1,1>. The voltage −V is applied to the non-selected memory cells MC0<0,0>, MC0<0,2>, MC0<2,0>, and MC0<2,2> that are connected to the non-selected word lines WL0<0> and WL0<2> and the non-selected bit lines BL0<0> and BL0<2>. The voltage of 0 V is applied to other memory cells MC0, namely, the non-selected memory cells (hereinafter referred to as a “semi-selected memory cell”) MC0<1,0>, MC0<1,2>, MC0<0,1>, and MC0<2,1> that are connected to only one of the selected word line WL0<1> and the selected bit line BL0<1>.

In this case, an element used in a memory cell MC is required to have a current-voltage characteristic in which a current does not flow under a reverse bias less than a voltage −V, and a steep current increase is obtained under a forward bias. The use of such an element as the memory cell MC enables the set operation and the reset operation to be performed only in the selected memory cell MC0<1,1>.

Next, the bipolar operation will be described.

For the bipolar operation, basically it is necessary to consider the following points, namely, (1) the current is bi-directionally passed through the memory cell MC unlike in the unipolar operation, (2) an operating speed, an operating current, and an operating voltage are changed from those of the unipolar operation, and (3) the bias is applied to the semi-selected memory cell MC.

FIG. 5 is a view illustrating the point (3) and the state in which the bias is applied to the memory cell array 1 during the bipolar operation. In FIG. 5, the predetermined voltage V (for example, 3 V) is applied to the selected word line WL0<1>, and the voltage V/2 is applied to other word lines WL0<0> and WL0<2>. The predetermined voltage of 0 V is applied to the selected bit line BL0<1>, and the voltage V/2 is applied to other bit lines BL0<0> and BL0<2>.

In this case, the voltage of V/2 is applied to the semi-selected memory cells MC0<1,0>, MC0<1,2>, MC0<0,1>, and MC0<2,1>. Accordingly, in the bipolar operation, it is necessary to prepare a rectifying element in which the current is not passed at the voltage of V/2 or less.

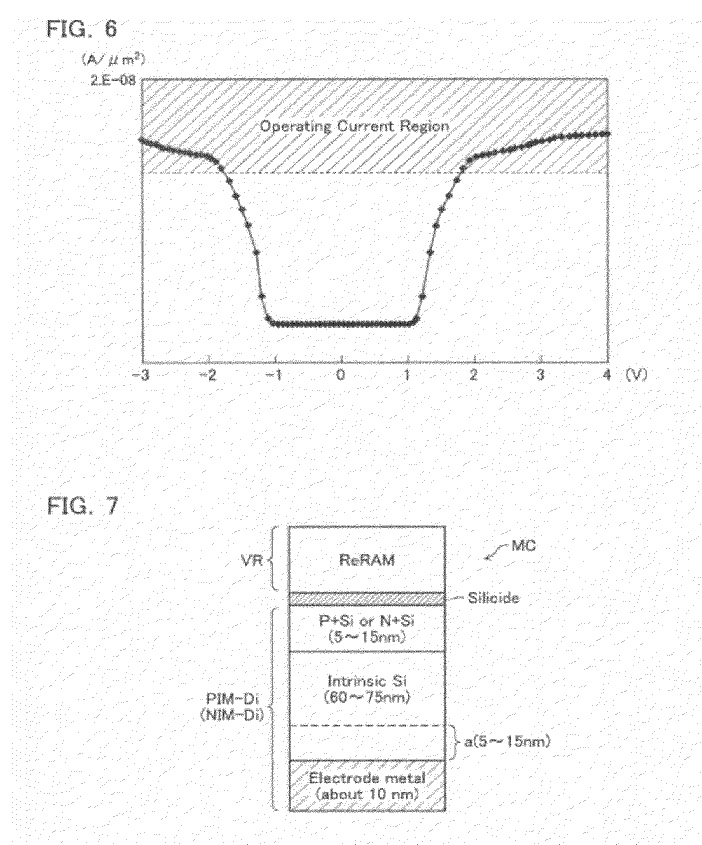

FIG. 6 illustrates an example of a current-voltage characteristic of a rectifying element desirable in the bipolar operation. FIG. 6 illustrates the current-voltage characteristic when V is set at to 2 V. In this case, an off-current is suppressed in the off-region near the voltage of −1 V corresponding to −V/2, and an reverse current is passed within an operating current region necessary for the set operation and the reset operation in the on-region near the voltage of −2 V corresponding to −V.

The bias applied states in the unipolar operation and the bipolar operation have been described above, and it is necessary that the rectifying element used in the unipolar operation and the bipolar operation have the small off-current.

It is desirable to increase a film thickness of the rectifying element in order to suppress the off-current. In this case, however, it is difficult to microfabricate the memory cell MC due to an aspect ratio in forming the memory cell MC. Thus, there is a conflicting problem between the microfabrication of the memory cell MC and improvement of the current-voltage characteristic, and this conflicting problem exists in both the unipolar operation and the bipolar operation.

In order to implement the nonvolatile semiconductor storage device in which the variable resistive element is used, therefore, it is necessary to prepare the rectifying element having the following conditions. That is, (1) the thinning and the microfabrication of the memory cell MC are easy to perform, and a variation in characteristic of the memory cell is decreased, (2) the rectifying element has a high breakdown voltage against a high voltage applied thereto, and can withstand the operation many times, and (3) the current can sufficiently be secured in the on-region while the off-current can be suppressed in the off-region.

Among others, it is necessary that the off-current be suppressed in the off-region while the memory cell MC is thinned from the standpoint of the microfabrication.

When the off-current cannot be suppressed, not only is the set operation mistakenly performed to the non-selected memory cell MC, but also the read operation cannot be performed or low power consumption cannot be achieved. When power efficiency is degraded due to the increase in off-current, the number of bays that can simultaneously be activated is restricted, possibly leading to the degradation of performance. In consideration of an interconnection resistance, it is necessary to divide the memory cell array 1 into a smaller size, which possibly leads to enlargement of a chip size.

<Rectifying Element>

Therefore, in the first embodiment, the rectifying element whose on-off ratio is improved is used in the memory cell MC.

A PIN diode of a comparative example will be described before the description of the rectifying element of the first embodiment.

FIG. 58 is a view illustrating a structure of a memory cell MC′ in which the PIN diode is used. Referring to FIG. 58, the memory cell MC′ includes an electrode metal having a thickness of about 10 nm that is connected to the word line WL or the bit line BL, an N+Si layer that is an N-type semiconductor layer having a thickness of 5 to 15 nm, an intrinsic Si layer that is an intrinsic semiconductor layer having a thickness of 60 to 75 nm, a P+Si layer that is a P-type semiconductor layer having a thickness of 5 to 15 nm, a silicide layer, and an ReRAM layer from the bottom. The PIN diode that is the rectifying element includes the layers from the N-type semiconductor layer to the P-type semiconductor layer. The thickness of the PIN diode depends on the generation. For example, the thickness of the PIN diode ranges from 70 to 105 nm.

FIG. 59 is a view illustrating a state of an energy band when the forward bias is applied to the PIN diode having the structure of FIG. 58. When the forward bias is applied to the PIN diode, energy of electrons in the N+Si layer is raised. In this case, electrons in the N+Si layer having higher energy than that of the lower edge of a conduction band of the P+Si layer increase in density. As shown in FIG. 59, such electrons diffuse from the conduction band of the N+Si layer to the conduction band of the P+Si layer, while holes diffuse from the conduction band of the P+Si layer to the conduction band of the N+Si layer. Although a state of the current such as recombination current and diffusion current is different according to the applied voltage, basically a forward current is passed from the P+Si layer to the N+Si layer.

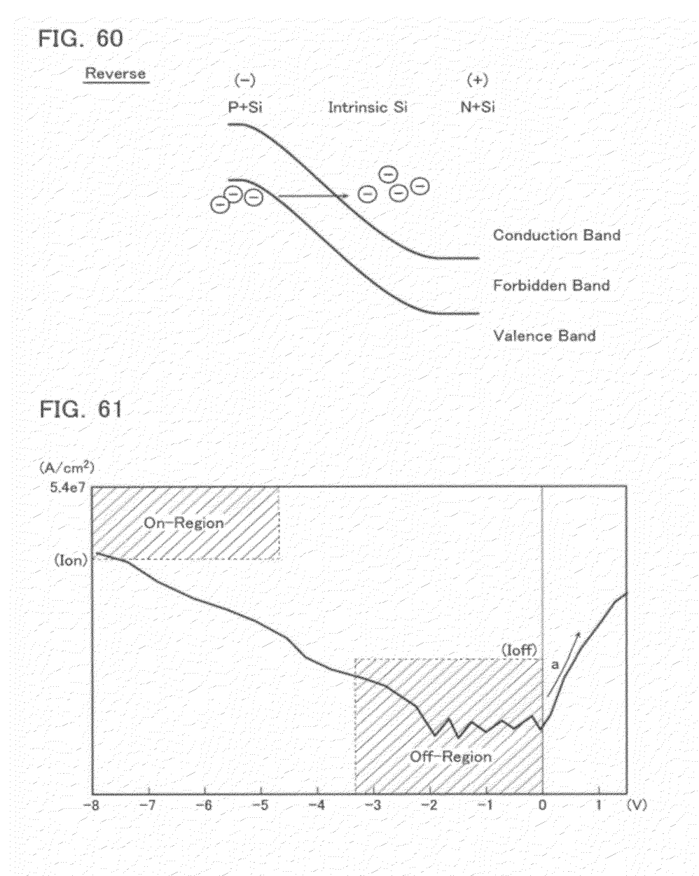

FIG. 60 is a view illustrating a state of the energy band when the reverse bias is applied to the PIN diode having the structure of FIG. 58. When the reverse bias is applied to the PIN diode, the energy of electrons in the N+Si layer is decreased. In this case, the electrons in the N+Si layer having higher energy than that of the lower edge of the conduction band of the P+Si layer decrease in density, diffusion of electrons from the N+Si layer to the P+Si layer is not generated unlike in the application of the forward bias. However, since the energy band is vertically expanded with increasing reverse bias, electrons in a valence band of the P+Si layer easily tunnel through a forbidden band. Therefore, the reverse current starts to be passed.

FIG. 61 illustrates a current-voltage characteristic of the PIN diode. FIG. 61 illustrates a target value Ioff (about 5 A/cm² or less) of the off-current in the off-region and a target value Ion (about 1×10⁵ A/cm² or more) of the reverse current in the on-region.

As can be seen from FIG. 61, when the forward bias is applied, the current value rapidly rises from the neighborhood of 0 V as illustrated by an arrow a of FIG. 61. For example, the current of about 5×10⁴ A/cm² is passed when the voltage of 1 V is applied as the forward bias. On the other hand, the current value gently rises at an exponential rate when the reverse bias is applied. As a result, the off-current is insufficiently suppressed near the voltage of −3 V is in becomes the off-region while the necessary reverse current is not obtained near the voltage of −5 V that is in the on-region. Furthermore, one may consider applying a larger reverse bias to obtain a sufficient reverse current. However, the large reverse bias adversely affects a CMOS circuit constituting a peripheral circuit of the memory cell array 1.

As described above, in order to perform the bipolar operation of the memory cell MC, for example, it is necessary to prepare a rectifying element having current-voltage characteristic in which a current is sufficiently passed in the on-region while an off-current is suppressed in the PIN diode.

Therefore, a rectifying element illustrated in FIG. 7 is used in the first embodiment. FIG. 7 is a view illustrating a structure of the memory cell MC in the nonvolatile semiconductor storage device of the first embodiment.

Referring to FIG. 7, an electrode metal that is a metal layer having the thickness of about 10 nm, an intrinsic Si layer that is the intrinsic semiconductor layer having the thickness of 60 to 75 nm, a P+Si layer that is a P-type semiconductor layer having the thickness of 5 to 15 nm or a N+Si layer that is the N-type semiconductor layer having the thickness of 5 to 15 nm, a silicide layer, and an ReRAM layer that is the memory element are sequentially stacked from the bottom in the memory cell MC of the first embodiment. The rectifying element includes the layers from the P+Si layer or the N+Si layer to the electrode metal. Hereinafter the rectifying element of the first embodiment having the structure is referred to as a “PIM diode” or a “NIM diode”. The PIM diode will mainly be described below.

Note that “an intrinsic semiconductor layer” in this embodiment is not limited to a strict meaning: It means not only a semiconductor layer having no dopant at all, but also a semiconductor layer whose dopant concentration is extremely low (for example, 1×10¹⁹/cm³ or less). The same holds true for other embodiments of the invention.

The PIM diode has a structure in which the N+Si layer is substantially removed from the structure of the PIN diode of FIG. 58. Accordingly, as illustrated by a part a of FIG. 7, the memory cell MC can be formed thinner than the memory cell MC′ in which the PIN diode is used by the thickness of the N+Si layer (5 to 15 nm). As a result, the aspect ratio of the memory cell MC is reduced to easily microfabricate the memory cell MC compared with the memory cell MC′ in which the PIN diode is used.

Then an operation of the PIM diode will be described. The PIM diode in which TiN is used as the electrode metal will be described.

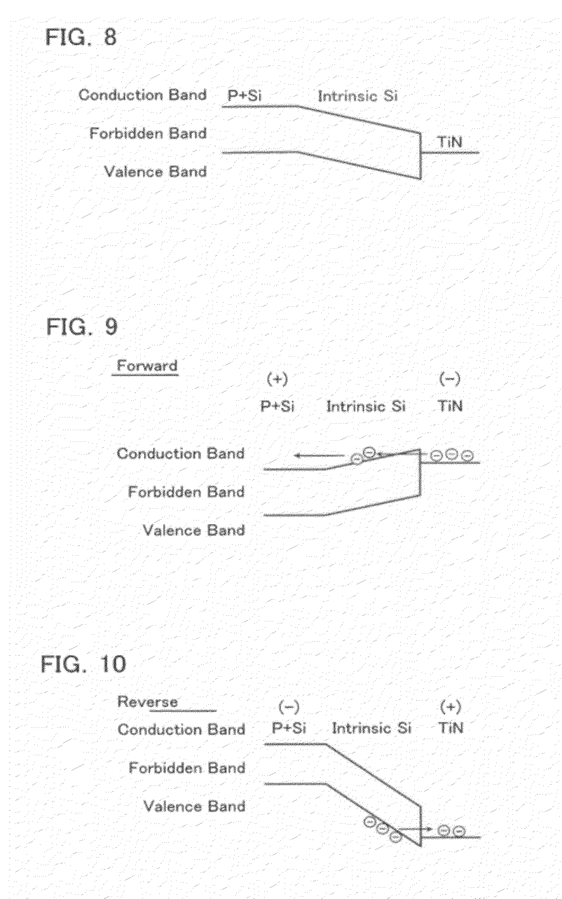

FIG. 8 is a view illustrating a state of an energy band in an equilibrium state of the PIM diode. For the PIM diode, as illustrated in FIG. 8, a Schottky barrier is formed between the intrinsic Si layer and the electrode metal (TiN).

At this point, when the forward bias is applied to the PIM diode, a level at the lower edge of the conduction band of the P+Si layer is lowered as illustrated in FIG. 9. Accordingly, the effective barrier against a Fermi level of the electrode metal (TiN) becomes small and electrons easily tunnel through the barrier. Therefore, electrons existing in the conduction band of the electrode metal (TiN) diffuse in the conduction band of the intrinsic Si layer on the P+Si layer side. As a result, the forward current is passed.

When the reverse bias is applied to the PIM diode, an upper edge of the valence band of the P+Si layer rises with respect to the Fermi level of the electrode metal (TiN) as illustrated in FIG. 10. Therefore, electrons existing in the valence band of the intrinsic Si layer on the P+Si layer side tunnel to the conduction band of the electrode metal (TiN). The fact that holes flow from the electrode metal (TiN) side to the P+Si layer side of the intrinsic Si layer also contributes to the tunneling. Additionally, a tunnel effect is obtained more easily than the PIN diode of the comparative example, because an energy difference between the valence band of the intrinsic Si layer and the electrode metal (TiN) becomes small. In the PIM diode, compared with the PIN diode, a larger reverse current can be passed during application of a reverse voltage while an off-current is suppressed in the off-region. Additionally, a desired reverse current may be obtained under a low bias of several volts because TiN that is the material for the electrode metal has a lower work function.

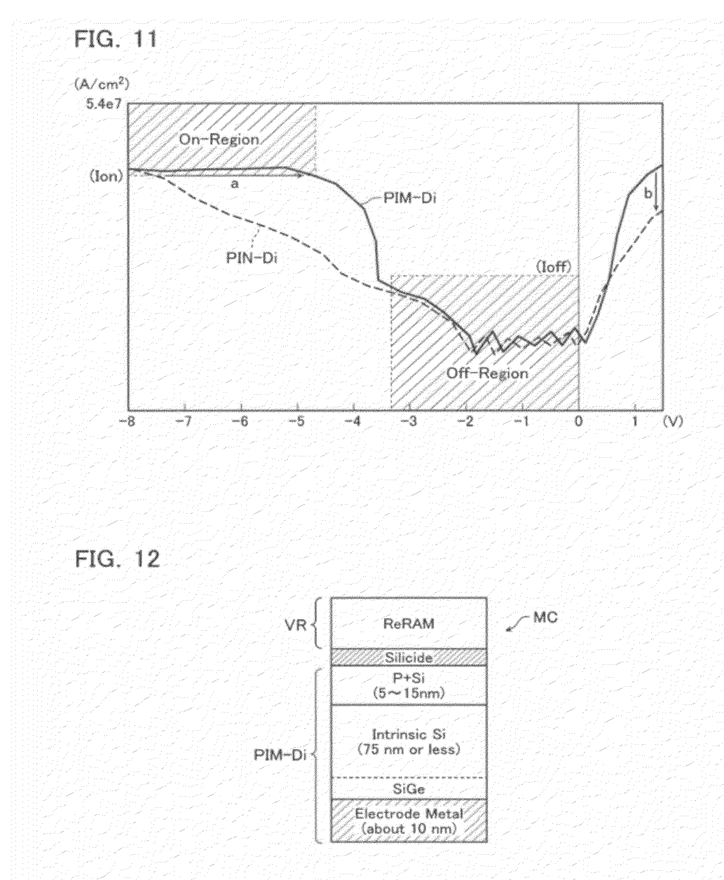

FIG. 11 illustrates a current-voltage characteristic of the PIM diode. The current-voltage characteristic of the PIN diode is also illustrated for the purpose of comparison.

As can be seen from FIG. 11, the use of the PIM diode largely improves the value of the reverse bias at which the desired reverse current starts to be passed. For example, when the target value Ion of the reverse current is set to 1×10⁵ A/cm² or more, it is necessary to apply the reverse bias of about −5 V for the PIM diode while it is necessary to apply the reverse bias of about −7 V for the PIN diode. The off-current is suppressed as low as the PIN diode.

For the PIN diode, one may consider that the current-voltage characteristic may be improved by thinning the N+Si layer or the intrinsic Si layer. However, in this case, only an inclination of the energy band is increased, but the current-voltage characteristic similarly to that of the PIM diode is not obtained. For the PIN diode, when a width of the intrinsic Si layer is decreased to obtain a sufficient on-current on the reverse direction side, although the sufficient on-current actually obtained, the off-current is considerably degraded by one order of magnitude or more. Therefore, there are generated such various problems that a malfunction of the memory cell MC or the power consumption cannot be suppressed.

In the first embodiment, TiN is used as the material for the electrode metal. Alternatively, any metallic material having the low work function and the Fermi level not lower than that of the N+Si layer may be used as the electrode metal. Particularly, the uses of ErSiₓ, HfSiₓ, YSiₓ, TaCₓ, TaNₓ, TiNₓ, TiCₓ, TiBₓ, LaBₓ, La, and LaN, which have the small work function, can enhance a rectifying characteristic of the PIM diode.

As described above, according to the first embodiment, the memory cell MC can be thinned by the N-type semiconductor layer compared with the PIN diode. As a result, the memory cell MC can cope with the increase in aspect ratio associated with the microfabrication to largely improve a possibility of forming the nonvolatile semiconductor storage device. At the same time, a larger reverse current can be obtained compared to the PIN diode. As a result, the improvement of the power consumption, the improvement of the read operation, the reduction of the chip area, and the improvements of the characteristics of the set operation and the reset operation can be achieved.

### Second Embodiment

In the nonvolatile semiconductor storage device of the first embodiment, the simplest PIM diode has been described as the rectifying element of the memory cell MC.

However, as described above, the Schottky barrier is generated between the intrinsic semiconductor layer and the metallic layer when the N-type semiconductor layer is simply removed to join the intrinsic semiconductor layer and the metallic layer like the PIM diode of the first embodiment. As a result, as illustrated by an arrow b of FIG. 11, the forward current is lost to some degree compared with the PIN diode.

Therefore, in a second embodiment of the invention, the PIM diode in which the Schottky barrier height (hereinafter referred to as an “SBH”) is reduced in the junction portion of the intrinsic semiconductor layer and the metallic layer is used as the rectifying element of the memory cell MC.

FIG. 12 is a view illustrating a structure of a memory cell MC of the second embodiment.

In the second embodiment, in the intrinsic semiconductor layer of the PIM diode or the NIM diode, a first region to which a material whose forbidden band has a width narrower than that of the intrinsic semiconductor layer is doped is formed near an interface of the electrode metal that is the metallic layer.

For example, Ge or Sn can be used as an additive when the intrinsic semiconductor layer is made of Si as illustrated in FIG. 12.

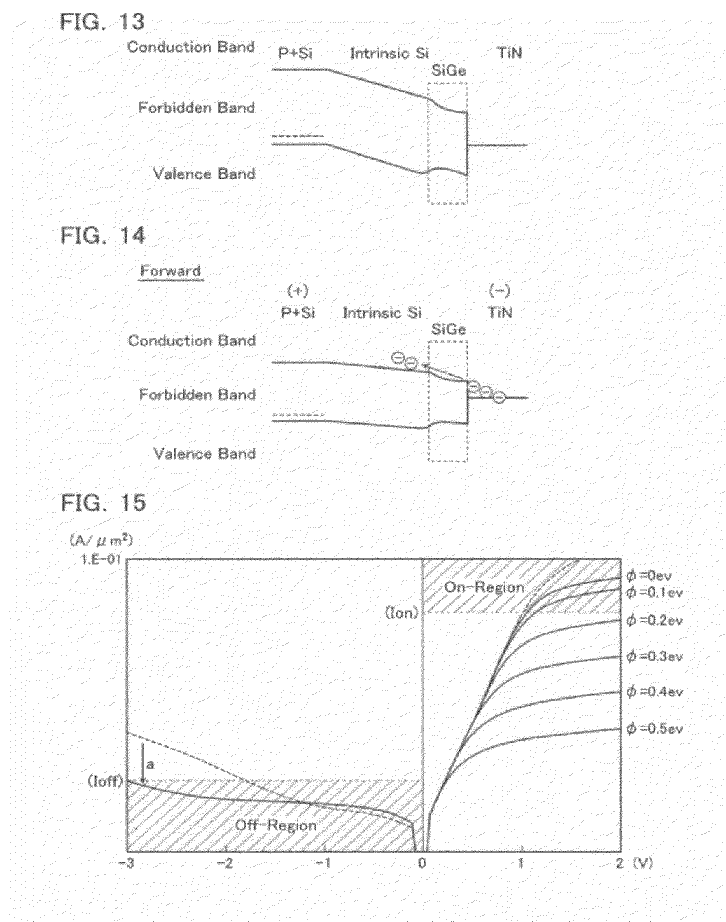

FIG. 13 illustrates the energy band in the equilibrium state of the PIM diode when Ge is doped to the intrinsic Si layer that is the intrinsic semiconductor layer.

As can be seen from FIG. 13, when Ge is doped to the vicinity of the interface between the intrinsic Si layer and the electrode metal (TiN), a SiGe region whose forbidden band is narrower than that of other region in the intrinsic Si layer is formed near the interface as illustrated by a broken line in FIG. 13.

As a result, the Schottky barrier that makes the forward current difficult to be passed when the forward bias is applied to the PIM diode is lowered as illustrated in FIG. 14. Additionally, mobility enhancement which is occurred by Ge incorporation improves forward current. Accordingly, the forward current can be passed at the same level as the PIN diode.

FIG. 15 is a view illustrating the current-voltage characteristic of the PIM diode when the SBH 9 is changed. In FIG. 15, a solid line indicates a characteristic of the PIM diode having the total film thickness of 60 nm, and a broken line indicates a characteristic of the PIN diode having the total film thickness of 60 nm.

As illustrated in FIG. 15, on the forward bias side, the forward current is increased with lowering SBH φ. For example, in the case where the target value Ion of the forward current is set to 1×10⁵ A/cm², the target value can sufficiently be achieved when the SBH φ is 0.1 eV or less.

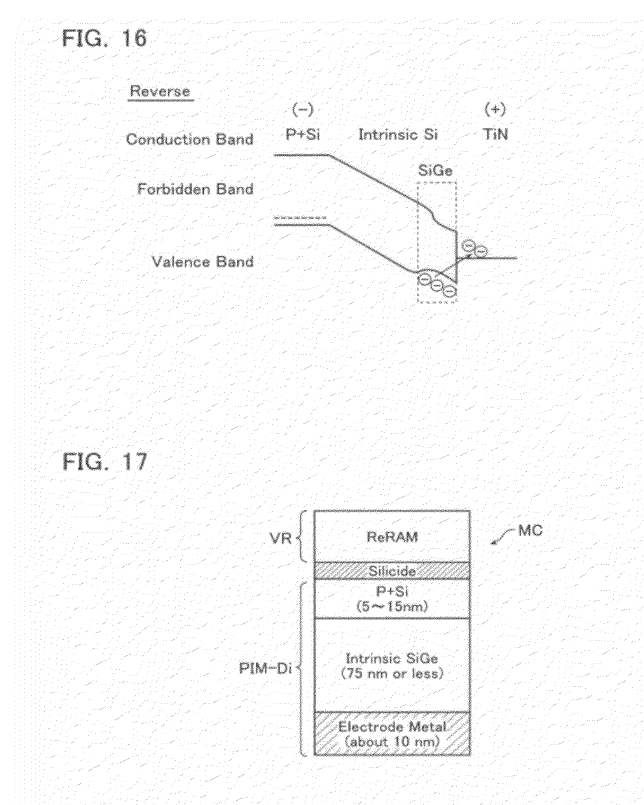

On the other hand, as illustrated in FIG. 16, when a reverse bias is applied to the PIM diode, the upper edge of the valence band of the intrinsic Si layer is bored upward in the SiGe region to narrow a band gap between the lower edge of the conduction band of the electrode metal (TiN) and the upper edge of the valence band of the intrinsic Si layer. Therefore, the reverse current starts to be passed by the smaller reverse bias. It could also be considered hole conduction increase.

As illustrated in FIG. 15, an off-current is greatly reduced compared with the PIN diode when a reverse bias is applied (an arrow a in FIG. 15). In the case where the target value Ioff of the off-current is set to about 1 to 10 A/cm², the target value can be achieved up to around −3 V that is in the off-region.

That is, when the PIM diode of the second embodiment is used, not only can an off-current further be reduced with the same film thickness as the PIN diode, but also the larger forward current can be passed than in the first embodiment.

As described above, according to the second embodiment, the improvements of the operating speeds of the set operation and the reset operation and the improvement of the characteristic of the read operation can be achieved while the low power consumption is maintained.

As to the structure of the memory cell MC of the second embodiment, structures illustrated in FIGS. 17 to 21 are conceivable in addition to the structure illustrated in FIG. 12.

FIG. 17 illustrates an example of the PIM diode having an intrinsic SiGe layer in which the whole intrinsic semiconductor layer is formed from the SiGe region by doping Ge to the whole intrinsic Si layer.

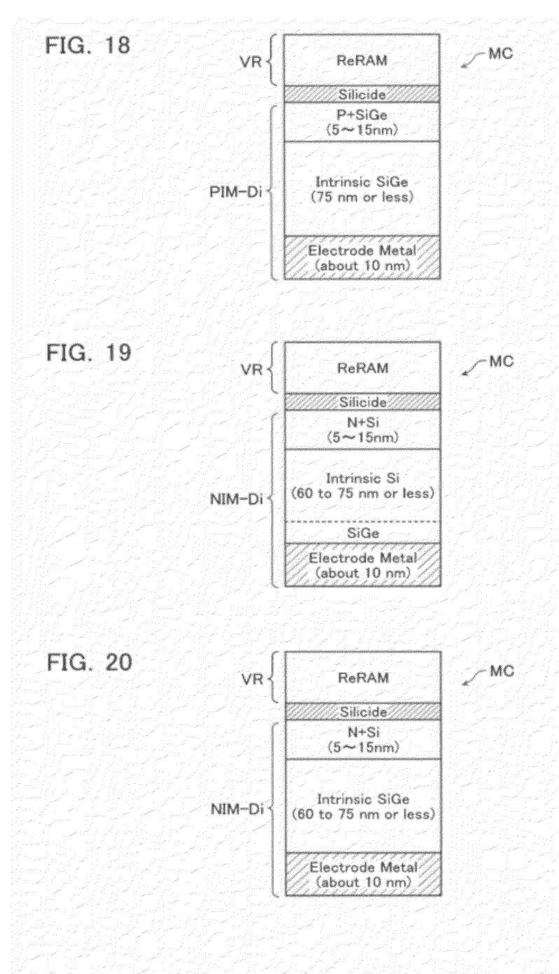

FIG. 18 illustrates an example of the PIM diode, in which the intrinsic semiconductor layer is formed as the intrinsic SiGe layer and the P-type semiconductor layer is formed as a P+SiGe layer by doping Ge to the whole P+Si layer.

For the structures illustrated in FIGS. 17 and 18, a step of switching SiGe to Si can be eliminated in the producing process although a leak current is increased because of the narrowed forbidden band.

FIGS. 19 to 21 illustrate examples of the NIM diodes.

FIG. 19 illustrates an example of the NIM diode having the SiGe region formed by doping Ge in the vicinity of the interface between the intrinsic Si layer and the electrode metal (TiN) similarly to the PIM diode of FIG. 12. For the structure of FIG. 19, because the SBH can be lowered similarly to the PIM diode of FIG. 12, a forward current can be increased while an off-current can be reduced compared with the first embodiment.

FIG. 20 illustrates an example of the NIM diode having the intrinsic SiGe layer in which the whole intrinsic semiconductor layer is formed from the SiGe region by doping Ge to the whole intrinsic Si layer.

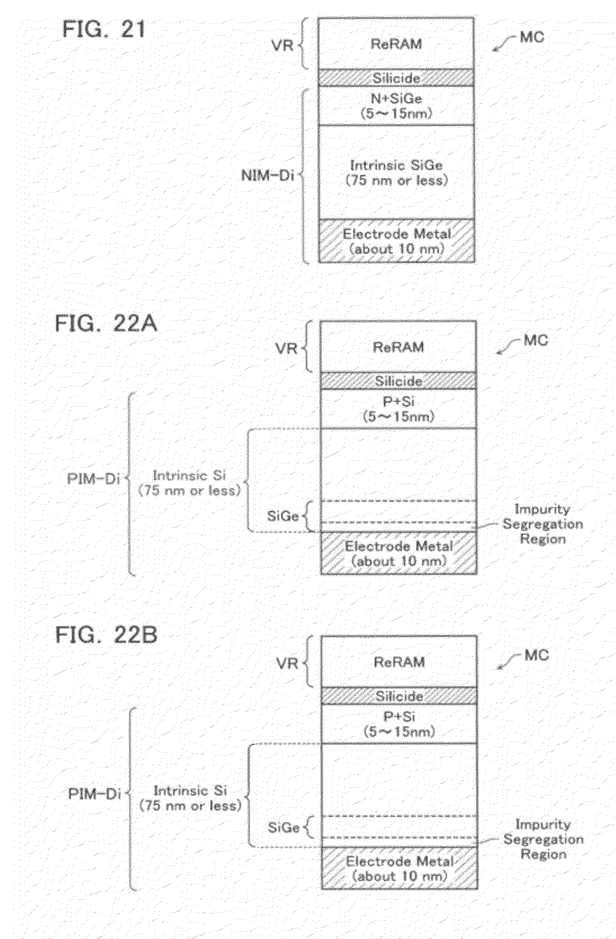

FIG. 21 illustrates an example of the NIM diode, in which the intrinsic semiconductor layer is formed as the intrinsic SiGe layer and the N-type semiconductor layer is formed as an N+SiGe layer by doping Ge to the whole N+Si layer.

For the structures illustrated in FIGS. 20 and 21, the step of switching SiGe to Si can be eliminated in the producing process.

### Third Embodiment

Similarly to the second embodiment, the PIM diode in which the influence of the Schottky barrier is reduced is used in a nonvolatile semiconductor storage device according to a third embodiment of the invention.

FIG. 22 illustrates a structure of a memory cell MC of the third embodiment.

The PIM diode of the memory cell MC of the third embodiment has a structure in which a dopant segregation region where a donor is segregated is formed as a second region in a boundary surface between the electrode metal (TiN) and the SiGe region of the intrinsic Si layer that is the intrinsic semiconductor layer of the PIM diode illustrated in FIG. 12.

The PIM diode of the memory cell MC of the third embodiment has a structure in which a dopant segregation region where a donor is segregated is formed as a second region in the intrinsic Si layer that is the intrinsic semiconductor layer of the PIM diode illustrated in FIG. 12. The dopant segregation region, if near a boundary surface between the intrinsic Si layer and an electrode metal (TiN), may be formed in the SiGe region as shown in FIG. 22A, or may be inserted between the SiGe region and the electrode metal as shown in FIG. 22B.
As used herein, the dopant segregation region means a region where the dopant such as As and P which has a concentration of, for example, about 1×10¹⁷ to 1×10²⁰/cm³ is doped into the intrinsic Si layer. Because the SBH can effectively be reduced by the formation of the dopant segregation region (the band is bent at the interface due to the existence of the dopant to be able to effectively decrease the width of the barrier), a larger forward current can be obtained than the PIM diode of the second embodiment.

It is to be noted that, in order that the effective decrease of the SBH is achieved (the barrier width is adjusted to facilitate the tunneling) while a merit of the use of the PIM diode is maintained, the dopant segregation region needs to be depleted. Therefore, it is necessary to form the dopant segregation region having the thickness of, for example, about 0.5 nm to 5 nm. In this respect, the dopant segregation region of the third embodiment differs from the N-type semiconductor layer of the PIN diode that is usually formed with the film thickness of about 5 to 15 nm as illustrated in FIG. 58. That is, the dopant segregation region of FIG. 22 is formed in order to decrease a resistance at the interface between the intrinsic semiconductor layer and the metallic layer, and electrons that are the carriers are supplied from the metallic layer.

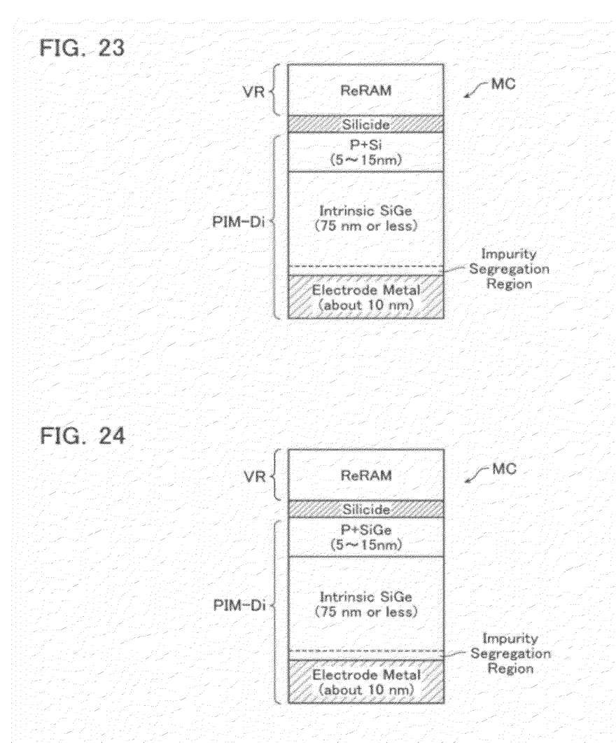

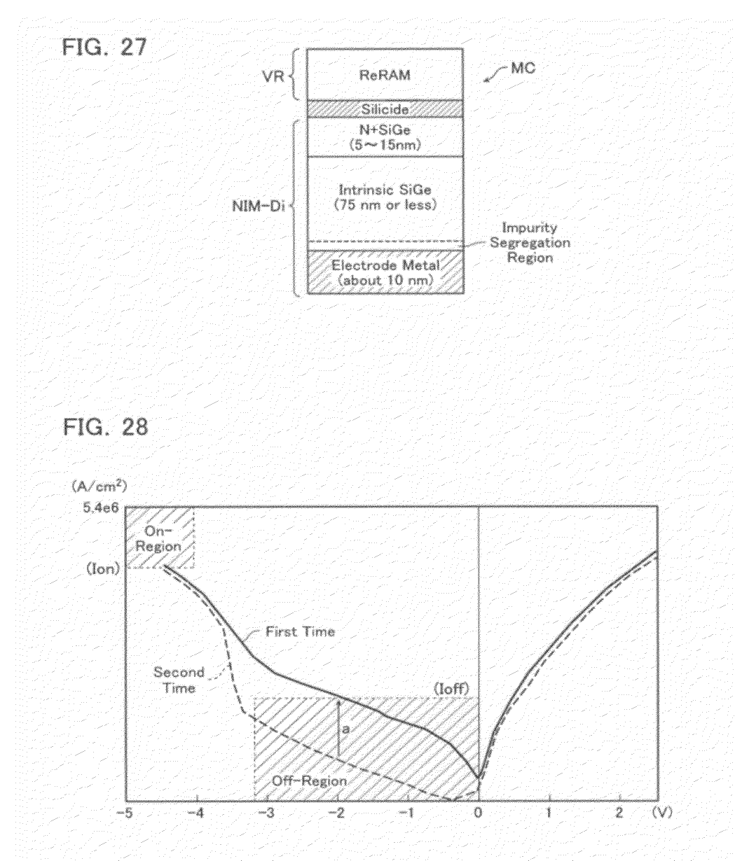

As to the structure of the memory cell MC of the third embodiment, structures illustrated in FIGS. 23 to 27 are conceivable in addition to the structure illustrated in FIG. 22.

FIGS. 23 and 24 illustrate examples of the memory cell MC in which the dopant segregation region is formed in the PIM diode of the second embodiment of FIGS. 17 and 18.

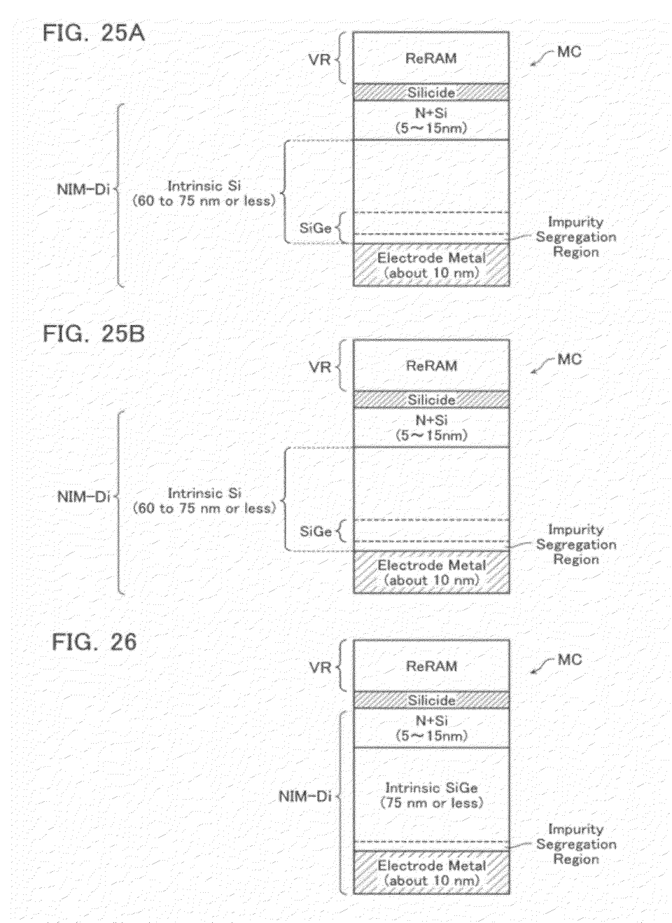

FIGS. 25 to 27 illustrate examples of the memory cell MC in which the dopant segregation region is formed in the NIM diode of the second embodiment of FIGS. 19 to 21. For the NIM diode, the segregated dopant is an acceptor such as B (boron).

FIGS. 25A and 25B to 27 illustrate examples of the memory cell MC in which the dopant segregation region is formed in the NIM diode of the second embodiment illustrated in FIGS. 19 to 21 respectively. In the case where the NIM diode has a SiGe region in the intrinsic Si layer, the dopant segregation region may be formed in the SiGe region as shown in FIG. 25A or may be inserted between the SiGe region and the electrode metal as shown in FIG. 25B. Note that for the NIM diode, the segregated dopant is an acceptor such as B (boron).

According to the PIM diode and the NIM diode of FIGS. 23 to 27, a larger forward current can be obtained than the PIM diode and the PIN diode, which have the similar structure in which the dopant segregation region is not provided in the intrinsic semiconductor layer.

### Fourth Embodiment

As described above, in order to perform the bipolar operation, it is necessary that the element in which a sufficient on-current is obtained while an off-current is suppressed be used as the rectifying element of the memory cell MC. Additionally, it is necessary that a reverse current be increased at an exponential rate up to about 1×10⁴ to 1×10⁷ A/cm² when an applied voltage is over the region of about −2 to −4 V. The PIM diodes of the first to third embodiments have the above-described conditions.

However, for the PIM diodes of the first to third embodiments, sometimes a current-voltage characteristic is degraded by repeatedly applying a bias as an electric stress.

FIG. 28 illustrates a change of the current-voltage characteristic when a DC stress voltage is applied to the PIM diode. In FIG. 28, a solid line indicates a current-voltage characteristic curve in the first-time application of the stress voltage, and a broken line indicates a current-voltage characteristic curve in the second-time application of the stress voltage. As illustrated by an arrow a in FIG. 28, in the second-time application of the stress voltage, the effect of suppressing the off-current when a voltage of 0 to −3 V is applied is degraded compared with the first-time application of the stress voltage.

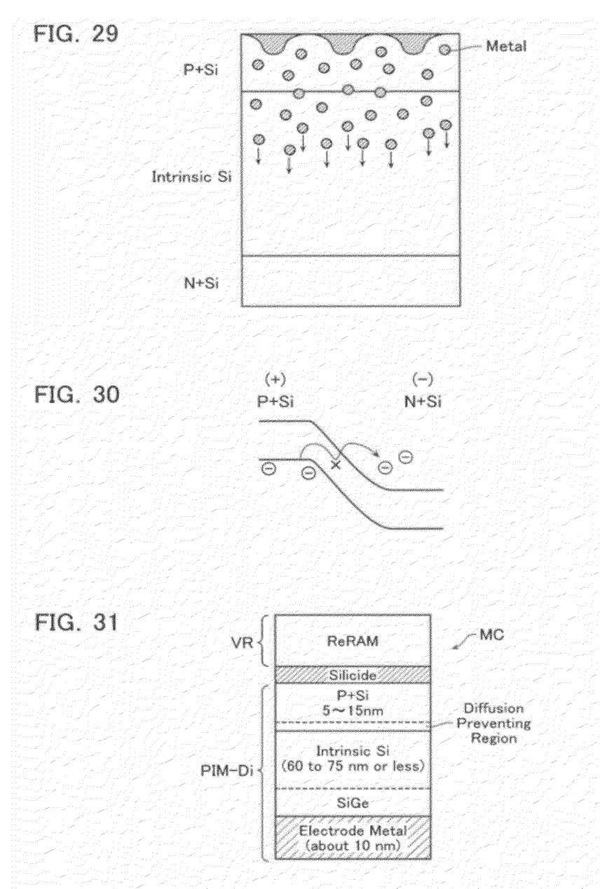

It is assumed that this disadvantage is caused by the following phenomenon. That is, heat or a current generated during reverse bias application causes an aggregate or Ti to be diffused from the silicide layer through the P-type semiconductor layer (P+Si). As a result, an energy is generated as illustrated in FIG. 30 to degrade the off-current suppression effect in the reverse bias. FIGS. 29 and 30 illustrate the case of the PIN diode. The same holds true for the PIM diode.

Therefore, in a configuration of a PIM diode or an NIM diode of a nonvolatile semiconductor storage device according to a fourth embodiment, a diffusion preventing region that prevents diffusion of the metal into the P-type semiconductor layer or the N-type semiconductor layer is provided in the PIM diode or NIM diode of the first to third embodiments.

FIG. 31 is a view illustrating a structure of a memory cell MC in the nonvolatile semiconductor storage device of the fourth embodiment.

In the PIM diode of the memory cell MC of the fourth embodiment, the diffusion preventing region that is a third region is formed near the interface with the intrinsic Si layer in the P+Si layer illustrated in FIG. 12.

At this point, the diffusion preventing region is made of a silicon oxide film (SiOₓ), a silicon nitride film (SiNₓ), a silicon carbide film (SiCₓ), an amorphous film, or a grain boundary.

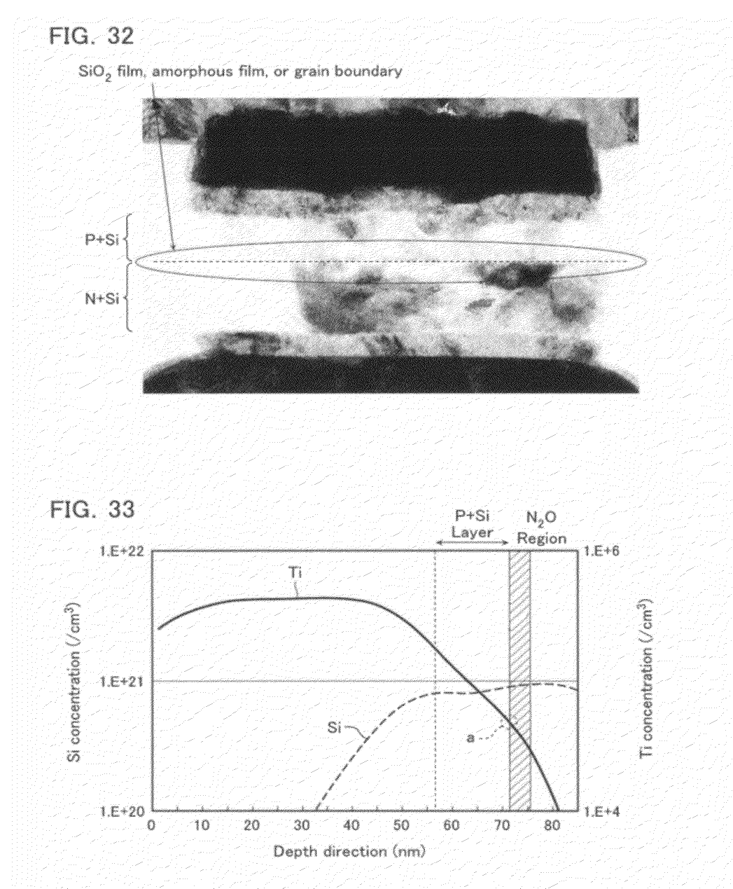

The effect of the PIM diode of the fourth embodiment will be described below with reference to reference data of FIGS. 32 to 34.

FIG. 32 is reference data illustrating an example in which the diffusion preventing region surrounded by a solid line is provided at the boundary between the P+Si layer and the N+Si layer. As illustrated by a broken line in FIG. 32, diffusion of the metal such as Ti is suppressed by the diffusion preventing region.

FIG. 33 is a view illustrating an example of the PIN diode and illustrates a relationship between a depth direction viewed from the P+Si layer side and concentrations of Si and Ti. As can be seen from FIG. 33, the concentration of Ti diffusing from the silicide layer is decreased at an exponential rate with increasing depths toward the P+Si layer and the N₂O layer, and particularly a decreasing rate of the Ti concentration is increased at the boundary between the P+Si layer and the N₂O layer.

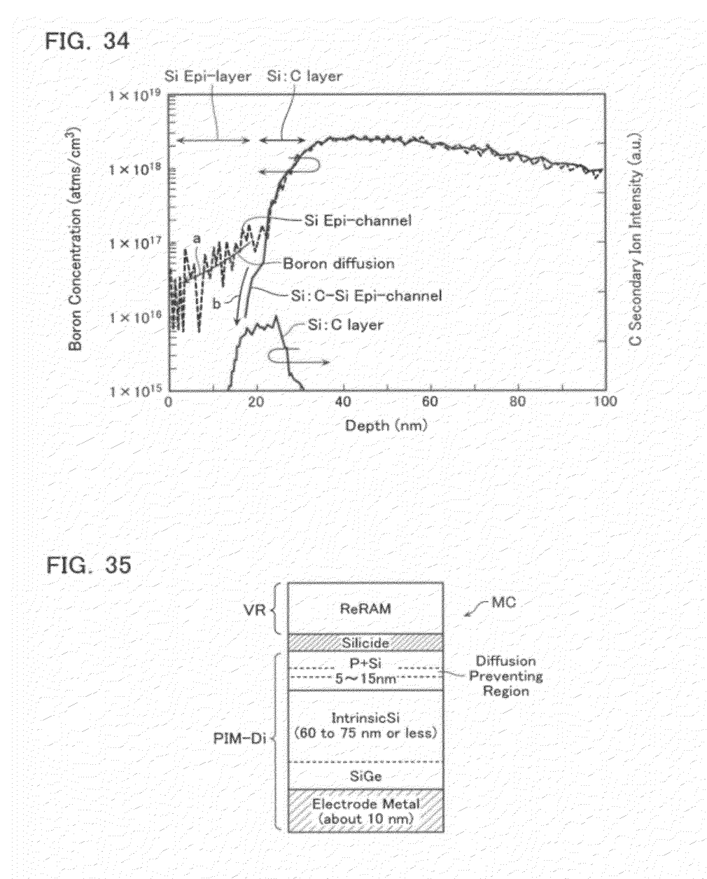

FIG. 34 illustrates an example of a polysilicon diode including Si layer/metallic layer/insulating layer/Si layer, and is a graph illustrating the concentration of B (boron). A solid line indicates the concentration of B (boron) in the case where C is doped to the Si layer to form a SiC layer, and a broken line indicates the concentration of B (boron) in the case where the SiC layer is not formed. As can be seen from the graph of FIG. 34, the concentration of B (boron) is gently decreased as illustrated by an arrow a in FIG. 34 in the case where the SiC layer is not formed, and the concentration of B (boron) is steeply decreased by the action of the SiC layer as illustrated by an arrow b in FIG. 34 in the case where the SiC layer is formed. Although the reference data does not deal with the diffusion of the metal such as Ti, it is considered that the same effect is obtained in Ti. Possibly the on-current is decreased when the insulating film is formed in the diffusion preventing region. However, as illustrated in FIG. 34, it is conceivable that the decrease in on-current can be reduced by the carbide film in which C is doped to the Si layer.

Although the reference data of FIGS. 32 to 34 do not relate to the PIM diode, the effect of the diffusion preventing region is similarly obtained in the PIM diode.

As described above, according to the fourth embodiment, the diffusion preventing region is provided in the vicinity of the interface between the P-type semiconductor layer and the silicide layer, an intermediate portion, or the vicinity of the interface between the P-type semiconductor layer and the intrinsic semiconductor layer in the PIM diode, so that the PIM diode degradation caused by the repetition of the set operation and the like can be suppressed. As a result, even if the set operation and the like are repeatedly performed, the false set operation can be suppressed in the memory cells MC except the selected memory cell MC while the low power consumption is maintained.

As to the structure of the memory cell MC of the fourth embodiment, structures illustrated in FIGS. 35 to 58 are conceivable in addition to the structure illustrated in FIG. 31.

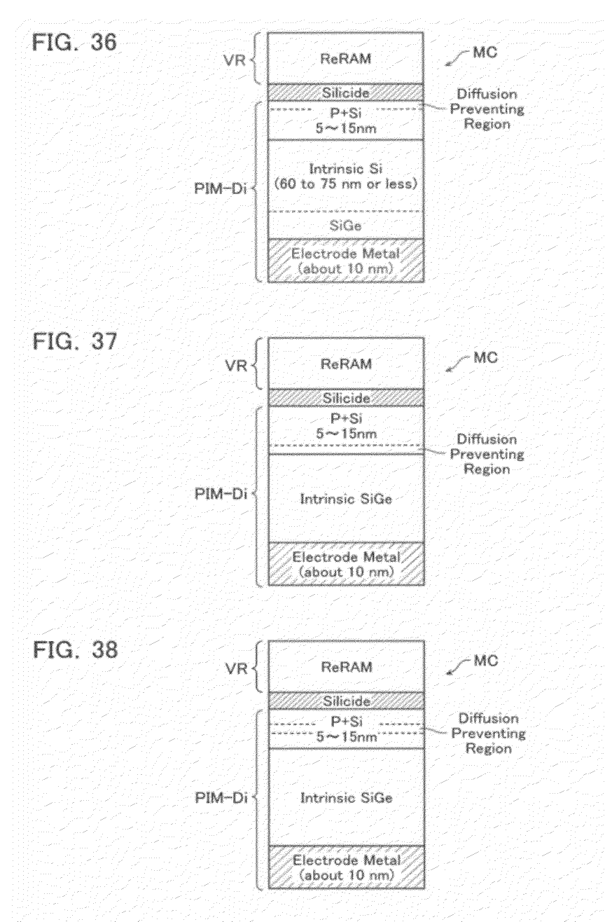

FIGS. 35 and 36 illustrate examples of the memory cell MC in which the diffusion preventing region is formed in the PIM diode of the second embodiment of FIG. 12. FIG. 35 illustrates an example in which the diffusion preventing region is formed in the middle of the P+Si layer, and FIG. 36 illustrates an example in which the diffusion preventing region is formed near the interface between the P+Si layer and the silicide layer.

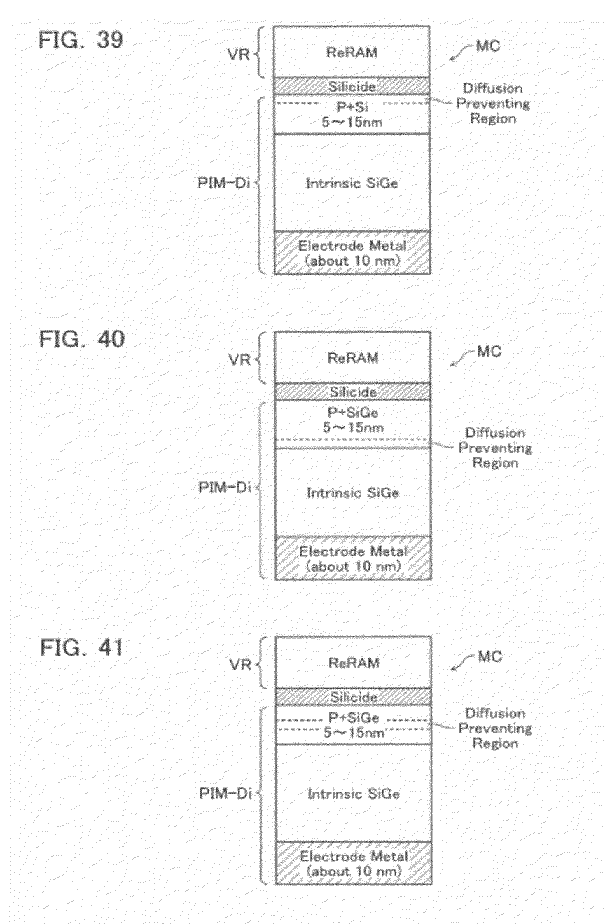

FIGS. 37 to 39 illustrate examples of the memory cell MC in which the diffusion preventing region is formed in the PIM diode of the second embodiment of FIG. 17. FIG. 37 illustrates an example in which the diffusion preventing region is formed near the interface between the P+Si layer and the intrinsic semiconductor layer, and FIG. 38 illustrates an example in which the diffusion preventing region is formed in the middle of the P+Si layer. FIG. 39 illustrates an example in which the diffusion preventing region is formed near the interface between the P+Si layer and the silicide layer.

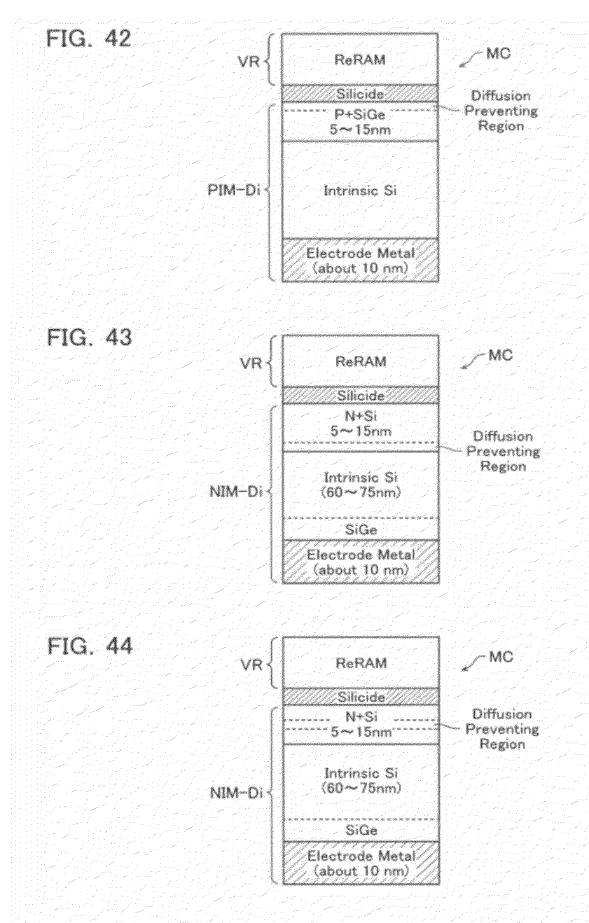

FIGS. 40 to 42 illustrate examples of the memory cell MC in which the diffusion preventing region is formed in the PIM diode of the second embodiment of FIG. 18. FIG. 40 illustrates an example in which the diffusion preventing region is formed near the interface between the P+Si layer and the intrinsic semiconductor layer, and FIG. 41 illustrates an example in which the diffusion preventing region is formed in the middle of the P+Si layer. FIG. 42 illustrates an example in which the diffusion preventing region is formed near the interface between the P+Si layer and the silicide layer.

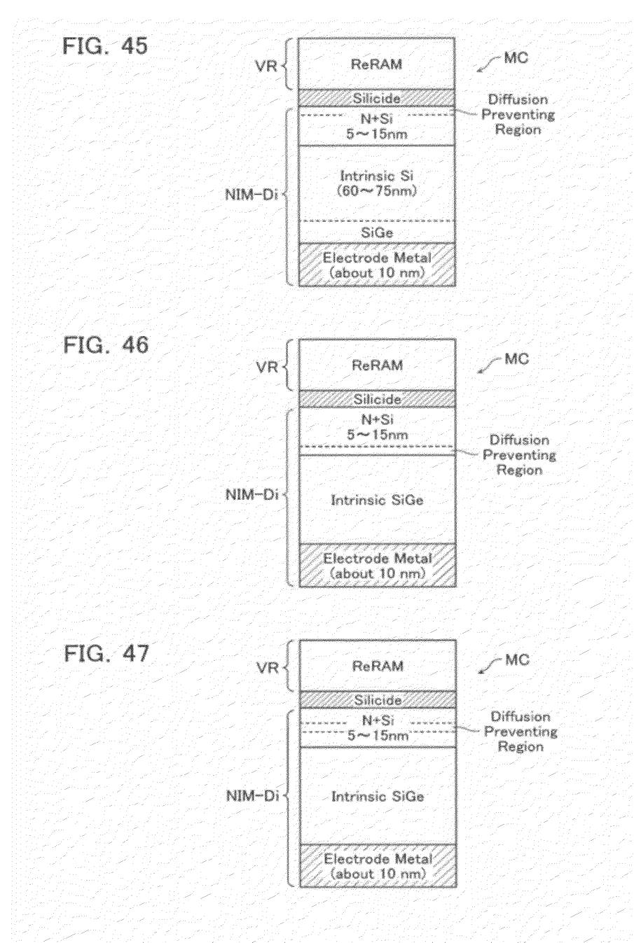

FIGS. 43 to 45 illustrate examples of the memory cell MC in which the diffusion preventing region is formed in the NIM diode of the second embodiment of FIG. 19. FIG. 43 illustrates an example in which the diffusion preventing region is formed near the interface between the N+Si layer and the intrinsic semiconductor layer, and FIG. 44 illustrates an example in which the diffusion preventing region is formed in the middle of the N+Si layer. FIG. 45 illustrates an example in which the diffusion preventing region is formed near the interface between the N+Si layer and the silicide layer.

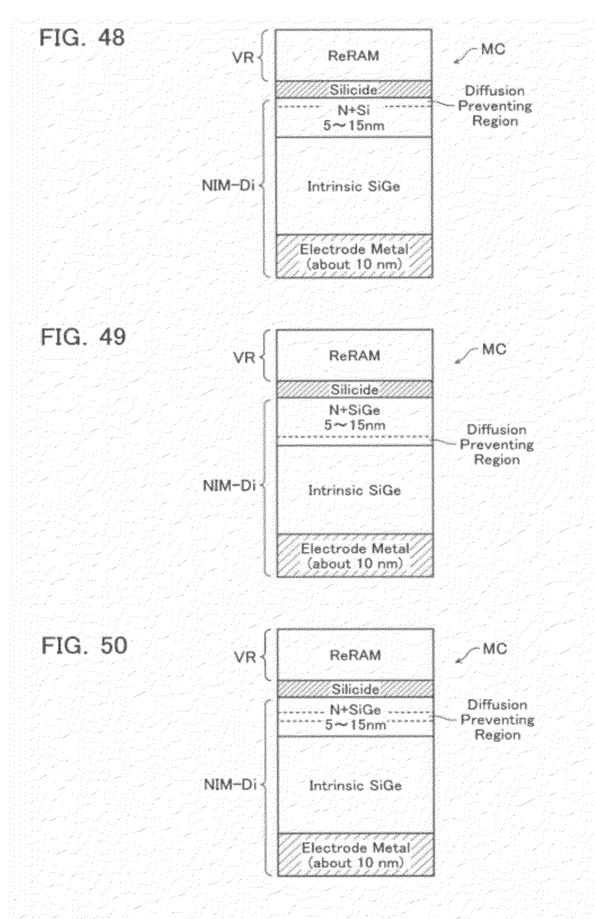

FIGS. 46 to 48 illustrate examples of the memory cell MC in which the diffusion preventing region is formed in the NIM diode of the second embodiment of FIG. 20. FIG. 46 illustrates an example in which the diffusion preventing region is formed near the interface between the N+Si layer and the intrinsic semiconductor layer, and FIG. 47 illustrates an example in which the diffusion preventing region is formed in the middle of the N+Si layer. FIG. 48 illustrates an example in which the diffusion preventing region is formed near the interface between the N+Si layer and the silicide layer.

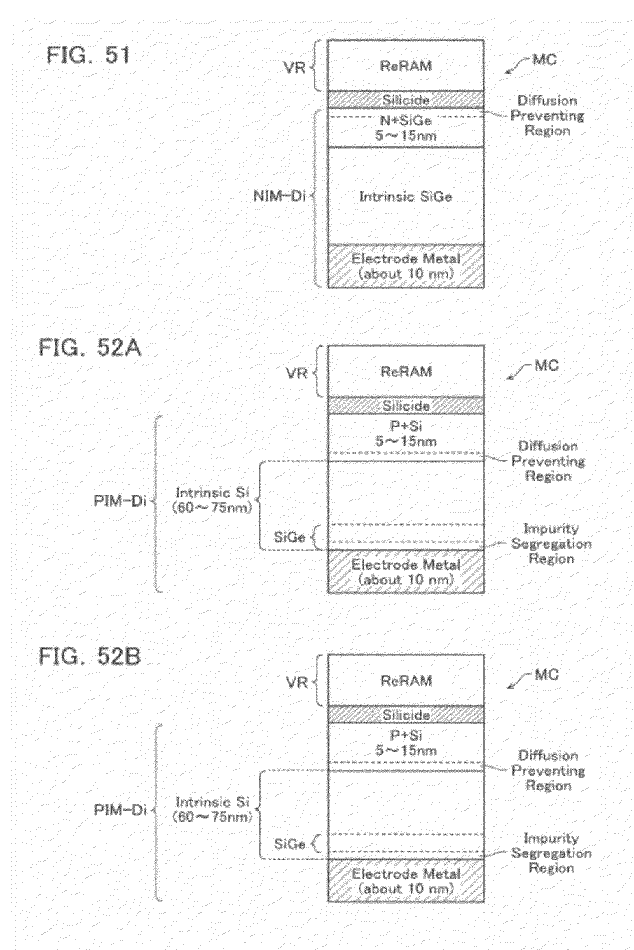

FIGS. 49 to 51 illustrate examples of the memory cell MC in which the diffusion preventing region is formed in the NIM diode of the second embodiment of FIG. 21. FIG. 49 illustrates an example in which the diffusion preventing region is formed near the interface between the N+Si layer and the intrinsic semiconductor layer, and FIG. 50 illustrates an example in which the diffusion preventing region is formed in the middle of the N+Si layer. FIG. 51 illustrates an example in which the diffusion preventing region is formed near the interface between the N+Si layer and the silicide layer.

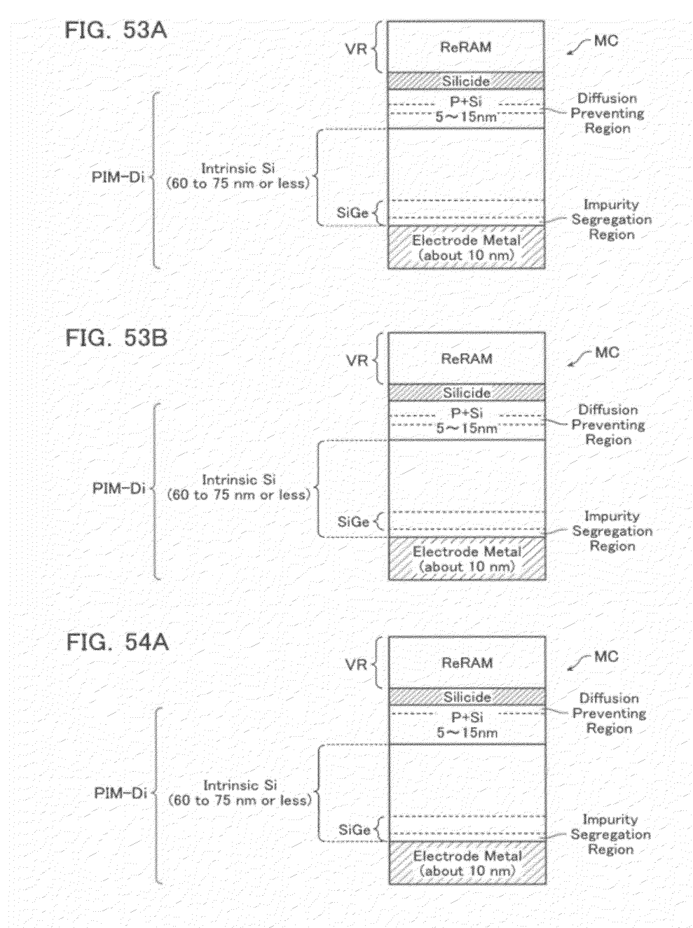

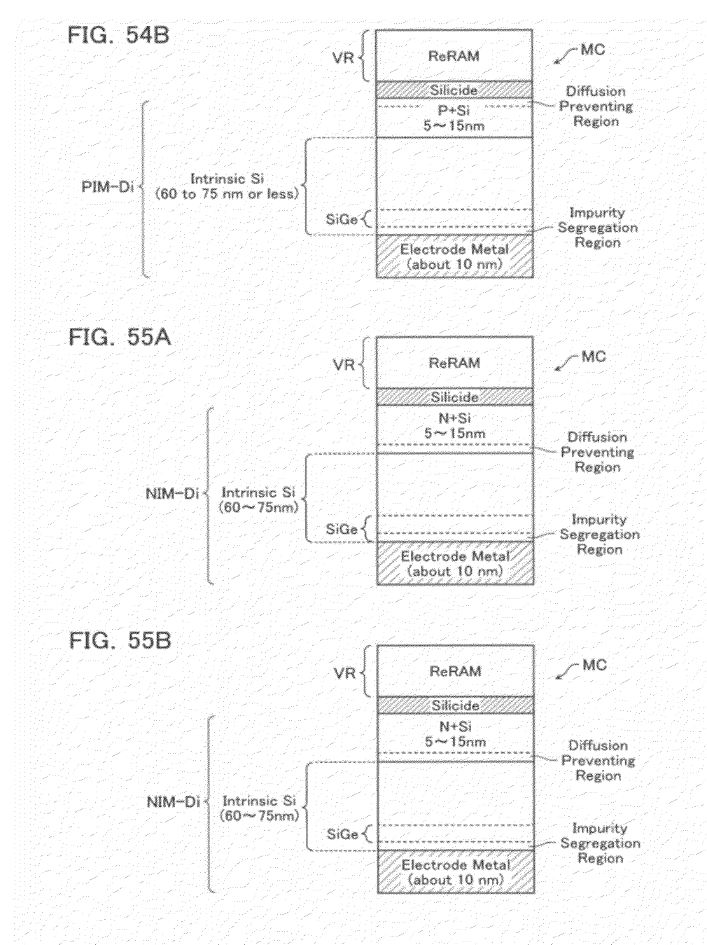

FIGS. 52A and 52B to 54A and 54B illustrate examples of the memory cell MC in which the diffusion preventing region is formed in the PIM diode of the third embodiment of FIGS. 22A and 22B, respectively. FIGS. 52A and 52B illustrate examples in which the diffusion preventing region is formed near the interface between the P+Si layer and the intrinsic semiconductor layer, and FIGS. 53A and 53B illustrate examples in which the diffusion preventing region is formed in the middle of the P+Si layer. FIGS. 54A and 54B illustrate examples in which the diffusion preventing region is formed near the interface between the P+Si layer and the silicide layer.

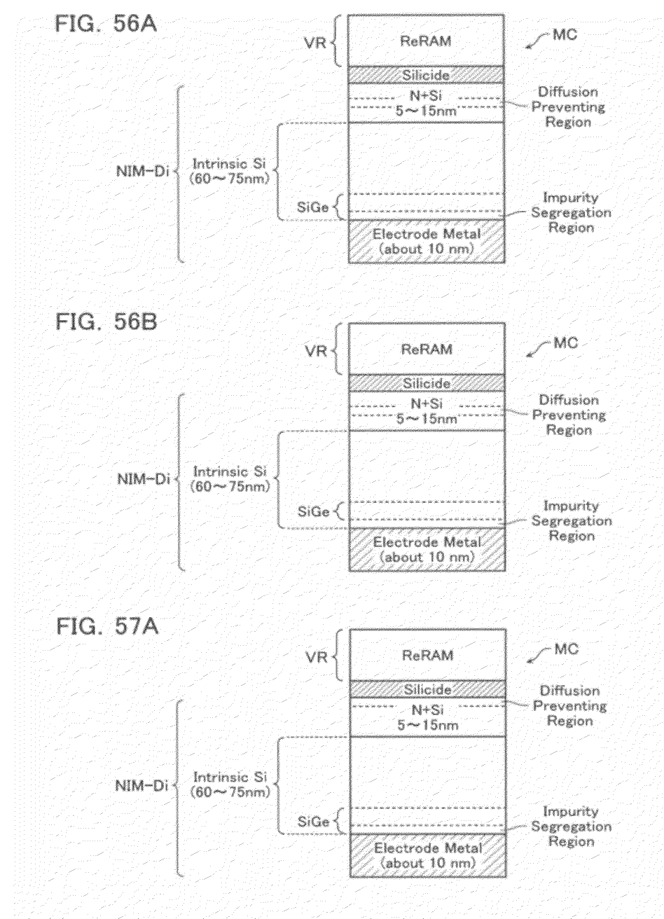

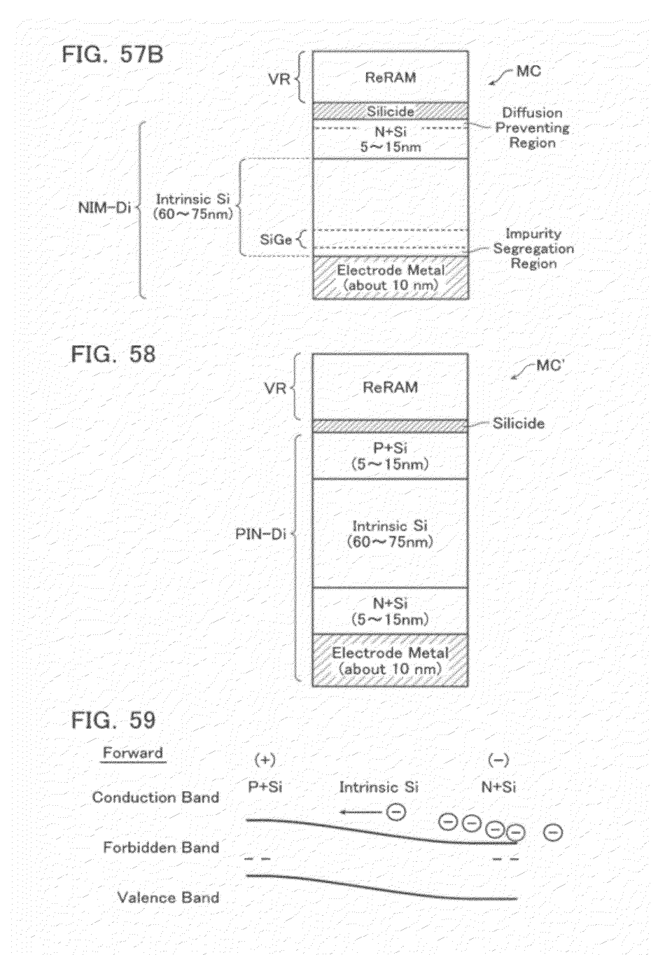

FIGS. 55A and 55B to 57A and 57B illustrate examples of the memory cell MC in which the diffusion preventing region is formed in the NIM diode of the third embodiment of FIGS. 25A and 25B, respectively. FIGS. 55A and 55B illustrate examples in which the diffusion preventing region is formed near the interface between the N+Si layer and the intrinsic semiconductor layer, and FIGS. 56A and 56B illustrate examples in which the diffusion preventing region is formed in the middle of the N+Si layer. FIGS. 57A and 57B illustrate examples in which the diffusion preventing region is formed near the interface between the N+Si layer and the silicide layer.

According to the PIM diodes and NIM diodes of FIGS. 35 to 57, the same effect as the PIM diode and NIM diode having the similar structure in which the diffusion preventing region is not provided in the intrinsic semiconductor layer is obtained, the metal diffusion and dopant diffusion caused by the repetitive operation can be suppressed compared with the PIM diode and NIM diode having the structures in which the diffusion preventing region is not provided, and therefore degradation of the operating characteristic of the memory cell MC can be suppressed.

[Materials for Memory Cell Array]

Finally, materials used in the memory cell arrays of the first to fourth embodiments are summarized as follows. x and y express an arbitrary composition ratio.

<P-type Semiconductor Layer and N-type Semiconductor Layer>

The P-type semiconductor layer of the PIM diode and the N-type semiconductor layer of the NIM diode can be selected from a group of Si, SiGe, SiC, Ge, C, III-V semiconductors such as GaAs, II-VI semiconductors such as ZnSe, oxide semiconductors, nitride semiconductors, carbide semiconductors, and sulfide semiconductors.

Preferably the material for the P-type semiconductor layer is one or a combination of P+Si, TiO₂, ZrO₂, InZnO₂, ITO, SnO₂ containing Sb, ZnO containing Al, AgSbO₃, InGaZnO₄, ZnO, and SnO₂.

Preferably the material for the N-type semiconductor layer is one or a combination of N+Si, NiOₓ, ZnO, Rh₂O₃, ZnO containing N, and La₂CuO₄.

<Rectifying Element>

The insulating layer constituting the insulating film in the rectifying element of the memory cell MC is selected from the following materials.

(1) Oxides
SiO₂, Al₂O₃, Y₂O₃, La₂O₃, Gd₂O₃, Ce₂O₃ r CeO₂, Ta₂O₅, HfO₂, ZrO₂, TiO₂, HfSiO, HfAlO, ZrSiO, ZrAlO, and AlSiO
AM₂O₄

where A and M are the same or different elements and selected from one of Al, Sc, Ti, V, Cr, Mn, Fe, Co, Ni, Cu, Zn, Ga, and Ge.

Examples of AM₂O₄ include Fe₃O₄, FeAl₂O₄, Mn₁₊ₓAl₂₋ₓO_{4+y}, CO₁₊ₓAl₂₋ₓO_{4+y}, and MnOₓ
AMO₃

where A and M are the same or different elements and selected from one of Al, La, Hf, Ta, W, Re, Os, Ir, Pt, Au, Hg, Tl, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn.

Examples of AMO₃ include LaAlO₃, SrHfO₃, SrZrO₃, and SrTiO₃.

(2) Oxynitrides
SiON, AlON, YON, LaON, GdON, CeON, TaON, HfON, ZrON, TiON, LaAlON, SrHfON, SrZrON, SrTiON, HfSiON, HfAlON, ZrSiON, ZrAlON, and AlSiON
Materials in which oxygen elements of the oxides indicated by (1) are partially substituted by a nitrogen element

In particular, preferably the insulating layer constituting the rectifying element is selected from a group of SiO₂, SiN, Si₃N₄, Al₂O₃, SiON, HfO₂, HfSiON, Ta₂O₅, TiO₂, and SrTiO₃.

As to the Si insulating film such as SIO₂, SiN, and SiON, the concentrations of the oxygen element and nitrogen element are not lower than 1×10¹⁸ atoms/cm³, respectively.

However, the plural insulating layers differ from each other in the barrier height.

A material including a dopant atom constituting a defect level or semiconductor/metal dot (quantum dot) may also be used as the insulating layer.

<Memory Element (Variable Resistive Element)>

For example, the following materials are used as the variable resistive element of the memory cell MC or the memory layer in the case where the memory function is incorporated in the rectifying element.

(1) Oxides
SiO₂, Al₂O₃, Y₂O₃, La₂O₃ Gd₂O₃, Ce₂O₃, CeO₂ Ta₂O₅, HfO₂, ZrO₂, TiO₂, HfSiO, HfAlO, ZrSiO, ZrAlO, and AlSiO
AM₂O₄

where A and M are the same or different elements and selected from one or a combination of Al, Sc, Ti, V, Cr, Mn, Fe, Co, Ni, Cu, Zn, Ga, and Ge.

Examples of AM₂O₄ include Fe₃O₄, FeAl₂O₄, Mn₁₊ₓAl₂₋ₓO_{4+y}, Co₁₊ₓAl₂₋ₓO_{4+y}, and MnOₓ.
AMO₃

where A and M are the same or different elements and selected from one or a combination of Al, La, Hf, Ta, W, Re, Os, Ir, Pt, Au, Hg, Tl, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn.

Examples of AMO₃ include LaAlO₃, SrHfO₃, SrZrO₃, and SrTiO₃.

(2) Oxynitrides
SiON, AlON, YON, LaON, GdON, CeON, TaON, HfON, ZrON, TiON, LaAlON, SrHfON, SrZrON, SrTiON, HfSiON, HfAlON, ZrSiON, ZrAlON, and AlSiON

For example, the memory element is made of a binary or ternary metal oxide or an organic material (including single layer film and nanotube). For example, carbon includes a two-dimensional structure such as the single layer film, nanotube, graphene, and fullerene. The metal oxides include the oxides indicated by (1) and the oxynitrides indicated by (2).

<Electrode Layer>

Single metallic element, plural mixtures, a silicide or oxide, and a nitride can be cited as the electrode layer used in the memory cell MC.

Specifically, for example, the electrode layer is made of Pt, Au, Ag, TiAlN, SrRuO, Ru, RuN, Ir, Ti, V, Cr, Mn, Fe, Co, Ni, Cu, TiN, TaN, LaNiO, Al, PtIrOₓ, PtRhOₓ, Rh, TaAlN, SiTiOₓ, WSiₓ, TaSiₓ, PdSiₓ, PtSiₓ, IrSiₓ, BrSiₓ, YSiₓ, HfSiₓ, NiSiₓ, CoSiₓ, TiSiₓ, VSiₓ, CrSiₓ, MnSiₓ, and FeSiₓ.

The electrode layer may simultaneously act as a barrier metallic layer or a bonding layer.

<Word Line and Bit Line>

For example, the conductive line that acts as the word line WL and the bit line BL of the memory cell array 1 is made of W, WN, Al, Ti, V, Cr, Mn, Fe, Co, Ni, Cu, TiN, WSiₓ, TaSiₓ, PdSiₓ, ErSiₓ, YSiₓ, PtSiₓ, HfSiₓ, NiSiₓ, CoSiₓ, TiSiₓ, VSiₓ, CrSiₓ, MnSiₓ, and FeSiₓ.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

As to the memory cell, various dispositions including the electrode and the line can be combined in addition to the memory cell in which the disposition of the memory element and the non-ohmic element is reversed vertically and the memory cell in which only the non-ohmic element is reversed vertically as illustrated in FIG. 2. The memory element can be disposed in any position of the memory cell within a range where the rectifying characteristic is not eliminated. For example, the memory element may also be used as the electrode or the barrier layer in the memory cell. The insulating film may have the memory function in which the changes in insulating characteristic, electric conduction, and dielectric characteristic due to ion trap or movement, filament, and the phase change are utilized.

In the embodiments, the first line has been described as the word line while the second line has been described as the bit line. Alternatively, the first line may be used as the bit line while the second line may be used as the word line.

What is claimed is:

1. A nonvolatile semiconductor storage device comprising:
a first line;
a second line that intersects the first line; and
a memory cell that includes a memory element and a non-ohmic element, the memory cell being provided at the intersection of the first line and the second line while the memory element and the non-ohmic element are series-connected, data being stored in the memory element according to a change of a resistance state,
the non-ohmic element including:
a metallic layer;
an intrinsic semiconductor layer that is joined to the metallic layer; and
a doped semiconductor layer that is joined to the intrinsic semiconductor layer and contains a first dopant.

2. The nonvolatile semiconductor storage device according to claim 1, wherein a doping concentration of the intrinsic semiconductor layer is 1×10¹⁹/cm³ or less.

3. The nonvolatile semiconductor storage device according to claim 1, wherein the first dopant is an acceptor.

4. The nonvolatile semiconductor storage device according to claim 1, wherein the first dopant is a donor.

5. The nonvolatile semiconductor storage device according to claim 1, wherein the doped semiconductor layer and the intrinsic semiconductor are made of silicon germanium (SiGe).

6. The nonvolatile semiconductor storage device according to claim 1, wherein the doped semiconductor layer of the non-ohmic element includes a third region that is made of any one of: a semiconductor having a band gap different from that of the doped semiconductor layer; a semiconductor having a crystal structure different from that of the doped semiconductor layer; an insulator; and
a grain boundary.

7. The nonvolatile semiconductor storage device according to claim 6, wherein the third region of the doped semiconductor layer of the non-ohmic element is disposed in any one of: a vicinity of an interface between another layer and an upper edge of the doped semiconductor layer; a vicinity of an interface between the intrinsic semiconductor layer and a lower edge of the doped semiconductor layer; and a middle of the doped semiconductor layer.

8. The nonvolatile semiconductor storage device according to claim 7, wherein the insulator included in the third region is made of one of a silicon oxide film (SiOₓ), a silicon nitride film (SiNₓ), and a silicon carbide film (SiCₓ).

9. A nonvolatile semiconductor storage device comprising:
a first line;
a second line that intersects the first line; and
a memory cell that includes a memory element and a non-ohmic element, the memory cell being provided at the intersection of the first line and the second line while the memory element and the non-ohmic element are series-connected, data being stored in the memory element according to a change of a resistance state,
the non-ohmic element including:
a metallic layer;
an intrinsic semiconductor layer that is joined to the metallic layer; and
a doped semiconductor layer that is joined to the intrinsic semiconductor layer and contains a first dopant,
the intrinsic semiconductor layer of the non-ohmic element including a first region in a vicinity of an interface between the intrinsic semiconductor layer and the metal layer, the first region being doped with a material whose forbidden band is narrower than a forbidden band of the intrinsic semiconductor layer.

10. The nonvolatile semiconductor storage device according to claim 9, wherein the intrinsic semiconductor layer is made of silicon (Si), and
the material doped to the first region is germanium (Ge) or tin (Sn).

11. The nonvolatile semiconductor storage device according to claim 9, wherein the doped semiconductor layer of the non-ohmic element includes a third region that is made of any one of: a semiconductor having a band gap different from that of the doped semiconductor layer; a semiconductor having a crystal structure different from that of the doped semiconductor layer; an insulator; and a grain boundary.

12. The nonvolatile semiconductor storage device according to claim 11, wherein the third region of the doped semiconductor layer of the non-ohmic element is disposed in any one of: a vicinity of an interface between another layer and an upper edge of the doped semiconductor layer; a vicinity of an interface between the intrinsic semiconductor layer and a lower edge of the doped semiconductor layer; and a middle of the doped semiconductor layer.

13. A nonvolatile semiconductor storage device comprising:
a first line;
a second line that intersects the first line; and
a memory cell that includes a memory element and a non-ohmic element, the memory cell being provided at the intersection of the first line and the second line while the memory element and the non-ohmic element are series-connected, data being stored in the memory element according to a change of a resistance state,
the non-ohmic element including:
a metallic layer;
an intrinsic semiconductor layer that is joined to the metallic layer; and
a doped semiconductor layer that is joined to the intrinsic semiconductor layer and contains a first dopant,
the intrinsic semiconductor layer of the non-ohmic element including a second region between the intrinsic layer and the metallic layer, a second dopant segregated in the second region in a boundary surface.

14. The nonvolatile semiconductor storage device according to claim 13, wherein a doping concentration of the second region ranges from 1×10¹⁷ to 1×10²⁰/cm³.

15. The nonvolatile semiconductor storage device according to claim 13, wherein a thickness of the second region ranges from 0.5 to 5 nm.

16. The nonvolatile semiconductor storage device according to claim 13, wherein the first dopant is an acceptor, and
the second dopant is a donor.

17. The nonvolatile semiconductor storage device according to claim 13, wherein the first dopant is a donor, and
the second dopant is an acceptor.

18. The nonvolatile semiconductor storage device according to claim 13, wherein the intrinsic semiconductor layer of the non-ohmic element includes a first region in a vicinity of an interface between the intrinsic semiconductor layer and the metal layer, the first region being doped with a material whose forbidden band is narrower than a forbidden band of the intrinsic semiconductor layer.

19. The nonvolatile semiconductor storage device according to claim 13, wherein the doped semiconductor layer of the non-ohmic element includes a third region that is made of any one of: a semiconductor having a band gap different from that of the doped semiconductor layer; a semiconductor having a crystal structure different from that of the doped semiconductor layer; an insulator; and
a grain boundary.

20. The nonvolatile semiconductor storage device according to claim 19, wherein the third region of the doped semiconductor layer of the non-ohmic element is disposed in any one of a vicinity of an interface between another layer and an upper edge of the doped semiconductor layer; a vicinity of an interface between the intrinsic semiconductor layer and a lower edge of the doped semiconductor layer; and a middle of the doped semiconductor layer.
